(19) United States
(12) Patent Application Publication
(10) Pub. No.: US 2026/0006952 A1
(43) Pub. Date: Jan. 1, 2026

(54) DISPLAY PANEL AND MANUFACTURING METHOD THEREOF AND DISPLAY DEVICE

(71) Applicant: Tianma Advanced Display Technology Institute (Xiamen) Co.,Ltd., Xiamen (CN)

(72) Inventors: Xiaoli LIU, Xiamen (CN); Haochen QIAN, Xiamen (CN)

(21) Appl. No.: 18/886,377

(22) Filed: Sep. 16, 2024

(30) Foreign Application Priority Data
Jun. 28, 2024 (CN) 202410867023.6

(51) Int. Cl. H01L 33/46; H01L 25/075; H01L 25/16; H01L 27/12; H01L 33/62

(52) U.S. Cl. CPC H10H 20/841; H01L 25/0753; H01L 25/167; H10D 86/441; H10D 86/60; H10H 20/857

(57) ABSTRACT

The present disclosure provides a display panel and a manufacturing method thereof, and a display device. The display panel includes a substrate, an array layer disposed on one side of the substrate, a light-emitting element disposed on a side of the array layer away from the substrate, and a first insulation structure disposed on a side of the array layer away from the substrate and surrounding at least a portion of the light-emitting element. The first insulation structure includes a first insulation subsection, where an orthographic projection of the first insulation subsection onto the substrate at least partially overlaps with an orthographic projection of the array layer onto the substrate.

### CROSS-REFERENCE TO RELATED APPLICATION

The present disclosure claims priority of Chinese Patent Application No. 202410867023.6, filed on Jun. 28, 2024, the entire content of which is hereby incorporated by reference.

### FIELD OF THE DISCLOSURE

The present disclosure generally relates to the field of display technology and, more particularly, relates to a display panel and a manufacturing method thereof, and a display device.

### BACKGROUND

With the continuous development of display technology, display panels have been widely used in people's work and personal life. In order to better meet people's needs, a display panel may be adjusted. For example, some structures in a display panel may be adjusted to improve the overall performance of the display panel.

### SUMMARY

One aspect of the present disclosure provides a display panel. The display panel includes a substrate, an array layer disposed on one side of the substrate, a light-emitting element disposed on a side of the array layer away from the substrate, and a first insulation structure disposed on a side of the array layer away from the substrate and surrounding at least a portion of the light-emitting element. The first insulation structure includes first insulation subsection, where an orthographic projection of the first insulation subsection onto the substrate at least partially overlaps with an orthographic projection of the array layer onto the substrate. The first insulation subsection includes a first side surface and a first bottom surface, the first side surface includes a first endpoint and a second endpoint, and the first endpoint is located on a side of the second endpoint away from the array layer. Along a first direction, a distance between the first endpoint and the light-emitting element is smaller than a distance between the second endpoint and the light-emitting element. The first bottom surface is connected to the second endpoint. An orthographic projection of the first bottom surface onto the substrate is located on a side, of an orthographic projection of the first side surface onto the substrate, away from an orthographic projection of the light-emitting element onto the substrate. The first direction is parallel to a plane where the substrate is disposed.

Another aspect of the present disclosure provides a method for preparing a display panel. The method includes providing a substrate, preparing an array layer, wherein the array layer is disposed on one side of the substrate, transferring a light-emitting element, wherein the light-emitting element is disposed on a side of the array layer away from the substrate, and preparing a first insulation structure. The first insulation structure is disposed on the side of the array layer away from the substrate, the first insulation structure surrounds at least part of the light-emitting element, and the first insulation structure includes a first insulation subsection. An orthographic projection of the first insulation subsection onto the substrate at least partially overlaps with an orthographic projection of the array layer onto the substrate. The first insulation subsection includes a first side surface and a first bottom surface, the first side surface includes a first endpoint and a second endpoint, and the first endpoint is located on a side of the second endpoint away from the array layer. Along a first direction, a distance between the first endpoint and the light-emitting element is smaller than a distance between the second endpoint and the light-emitting element. The first bottom surface is connected to the second endpoint. An orthographic projection of the first bottom surface onto the substrate is located on a side, of an orthographic projection of the first side surface onto the substrate, away from an orthographic projection of the light-emitting element onto the substrate. The first direction is parallel to a plane wherein the substrate is disposed.

Another aspect of the present disclosure provides a display device. The display device includes at least one display panel. The display panel includes a substrate, an array layer disposed on one side of the substrate, a light-emitting element disposed on a side of the array layer away from the substrate, and a first insulation structure disposed on a side of the array layer away from the substrate and surrounding at least a portion of the light-emitting element. The first insulation structure includes first insulation subsection, where an orthographic projection of the first insulation subsection onto the substrate at least partially overlaps with an orthographic projection of the array layer onto the substrate. The first insulation subsection includes a first side surface and a first bottom surface, the first side surface includes a first endpoint and a second endpoint, and the first endpoint is located on a side of the second endpoint away from the array layer. Along a first direction, a distance between the first endpoint and the light-emitting element is smaller than a distance between the second endpoint and the light-emitting element. The first bottom surface is connected to the second endpoint. An orthographic projection of the first bottom surface onto the substrate is located on a side, of an orthographic projection of the first side surface onto the substrate, away from an orthographic projection of the light-emitting element onto the substrate. The first direction is parallel to a plane where the substrate is disposed.

Other aspects of the present disclosure may be understood by those skilled in the art in light of the description, the claims, and the drawings of the present disclosure.

### BRIEF DESCRIPTION OF THE DRAWINGS

In order to more clearly illustrate the technical solutions of the exemplary embodiments of the present disclosure, the following briefly introduces the drawings for describing the embodiments. In some embodiments, the drawings introduced are only drawings of a part of the embodiments to be described in the present disclosure, rather than all the drawings. For a person skilled in the art, other drawings may be obtained based on these drawings without creative work.

FIG. 1 is a schematic structural diagram of a first display panel, in accordance with an embodiment of the present disclosure.

FIG. 2 is a first cross-sectional schematic diagram along the section line A-A′ in FIG. 1.

FIG. 3 is a second cross-sectional schematic diagram along the section line A-A′ in FIG. 1.

FIG. 4 is a third cross-sectional schematic diagram along the section line A-A′ in FIG. 1.

FIG. 5 is a fourth cross-sectional schematic diagram along the section line A-A′ in FIG. 1.

FIG. 6 is a fifth cross-sectional schematic diagram along the section line A-A′ in FIG. 1.

FIG. 7 is a sixth cross-sectional schematic diagram along the section line A-A′ in FIG. 1.

FIG. 8 is a seventh cross-sectional schematic diagram along the section line A-A′ in FIG. 1.

FIG. 9 is an eighth cross-sectional schematic diagram along the section line A-A′ in FIG. 1.

FIG. 10 is a ninth cross-sectional schematic diagram along the section line A-A′ in FIG. 1.

FIG. 11 is a tenth cross-sectional schematic diagram along the section line A-A′ in FIG. 1.

FIG. 12 is a cross-sectional schematic diagram of one first insulation structure, in accordance with an embodiment of the present disclosure.

FIG. 13 is a cross-sectional schematic diagram of another first insulation structure, in accordance with an embodiment of the present disclosure.

FIG. 14 is a cross-sectional schematic diagram of another first insulation structure, in accordance with an embodiment of the present disclosure.

FIG. 15 is an eleventh cross-sectional schematic diagram along the section line A-A′ in FIG. 1.

FIG. 16 is a first cross-sectional schematic diagram along the section line B-B′ in FIG. 1.

FIG. 17 is a second cross-sectional schematic diagram along the section line B-B′ in FIG. 1.

FIG. 18 is a third cross-sectional schematic diagram along the section line B-B′ in FIG. 1.

FIG. 19 is a schematic structural diagram of a second display panel, in accordance with an embodiment of the present disclosure.

FIG. 20 is a first cross-sectional schematic diagram along the section line C-C′ in FIG. 19.

FIG. 21 is a second cross-sectional schematic diagram along the section line C-C′ in FIG. 19.

FIG. 22 is a third cross-sectional schematic diagram along the section line C-C′ in FIG. 19.

FIG. 23 is a top view of a first metal wire routing section, in accordance with an embodiment of the present disclosure.

FIG. 24 is a schematic diagram of a first manufacturing process of a display panel, in accordance with an embodiment of the present disclosure.

FIG. 25 is a schematic diagram of a second preparation process of a display panel, in accordance with an embodiment of the present disclosure.

FIG. 26 is a schematic structural diagram of a display device, in accordance with an embodiment of the present disclosure.

### DETAILED DESCRIPTION

The present disclosure will be further described in detail hereinafter in conjunction with the accompanying drawings and embodiments. It should be noted that the specific embodiments described herein are merely used to explain the present disclosure, rather than to limit the present disclosure. It should also be noted that, for ease of description, only parts related to the present disclosure, rather than all structures, are shown in the accompanying drawings.

It should be noted that the terms “first”, “second”, and so on in the specification and claims of the present disclosure and the accompanying drawings are used to distinguish similar objects, and are not necessarily used to describe a specific order or sequence. It should be noted that the serial numbers used in this way may be interchanged where appropriate, so that the embodiments of the present disclosure described herein may be implemented in an order other than those illustrated or described herein. In addition, the terms “comprising” and “including” and any variations thereof are intended to cover non-exclusive inclusions. For example, a system, product, or device comprising a series of units is not necessarily limited to those steps or units clearly listed, but may include other units that are not clearly listed or inherent to these products or devices.

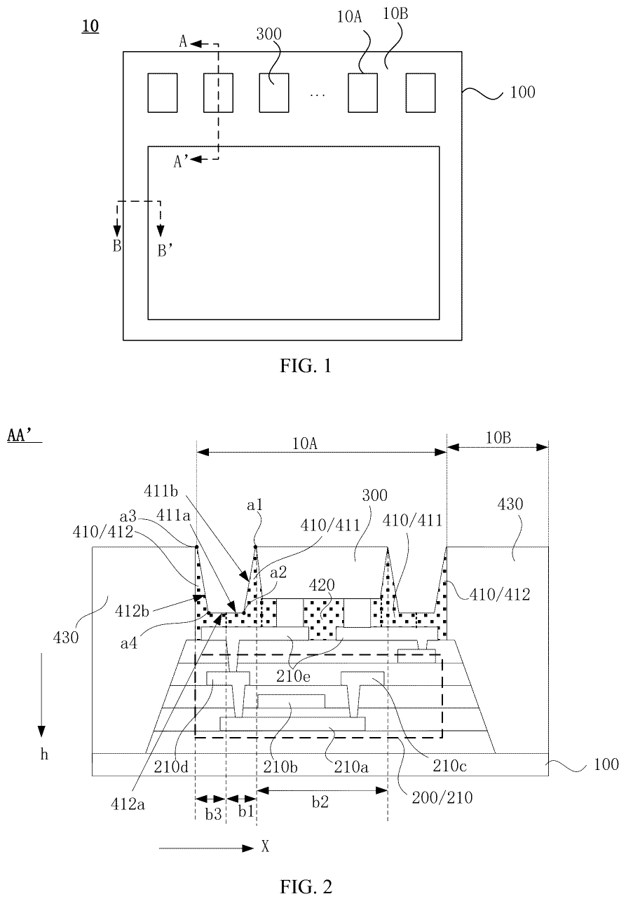

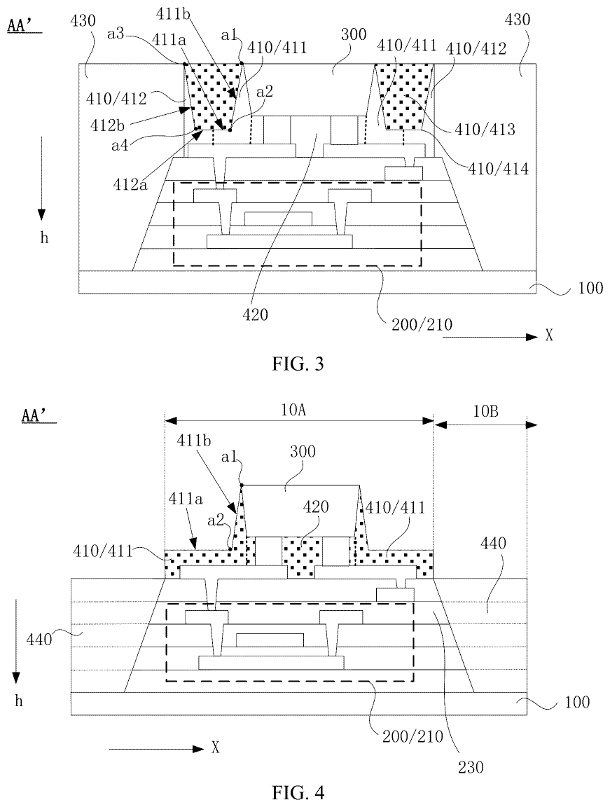

FIG. 1 is a schematic structural diagram of a first display panel, in accordance with an embodiment of the present disclosure, FIG. 2 is a schematic diagram of a first cross-section along a section line A-A′ in FIG. 1, FIG. 3 is a schematic diagram of a second cross-section along the section line A-A′ in FIG. 1, and FIG. 4 is a schematic diagram of a third cross-section along the section line A-A′ in FIG. 1. Referring to FIGS. 1-4, an embodiment of the present disclosure provides a display panel 10, which includes a substrate 100, an array layer 200 disposed on one side of the substrate 100, a light-emitting element 300 disposed on a side of the array layer 200 away from the substrate 100, and a first insulation structure 410 disposed on a side of the array layer 200 away from the substrate 100 and surrounding at least part of the light-emitting element 300. The first insulation structure 410 includes a first insulation subsection 411, and an orthographic projection of the first insulation subsection 411 onto the substrate 100 at least partially overlaps with an orthographic projection of the array layer 200 onto the substrate 100. The first insulation subsection 411 includes a first side surface 411b and a first bottom surface 411a. The first side surface 411b includes a first endpoint a1 and a second endpoint a2, the first endpoint a1 is located on a side of the second endpoint a2 away from the array layer 200. Along a first direction X, a distance between the first endpoint a1 and the light-emitting element 300 is smaller than a distance between the second endpoint a2 and the light-emitting element 300. The first bottom surface 411a is connected to the second endpoint a2. An orthographic projection of the first bottom surface 411a onto the substrate 100 is located on a side, of an orthographic projection of the first side surface 411b onto the substrate 100, away from an orthographic projection of the light-emitting element 300 onto the substrate 100. The first direction X is parallel to a plane where the substrate 100 is disposed.

The display panel 10 includes a substrate 100, an array layer 200, and a light-emitting element 300 located on one side of the substrate 100, where the light-emitting element 300 is disposed on a side of the array layer 200 away from the substrate 100. The array layer 200 may include a pixel circuit, which is electrically connected to the light-emitting element 300 and is configured to drive the light-emitting element 300 to emit light for display, thereby realizing the display function of the display panel 10. In some embodiments, the light-emitting element 300 may include a red light-emitting element, a blue light-emitting element, a green light-emitting element, etc. The pixel circuit drives light-emitting elements 300 of different colors to emit light for display, thereby realizing the color display performance of the display panel 10.

Exemplarily, referring to FIGS. 2-4, the array layer 200 is illustrated by taking a pixel circuit 210 as an example, where the pixel circuit 210 includes at least one transistor. The type of the pixel circuit 210 is not limited in the present disclosure, and may be adaptively adjusted based on the type and number of specific transistors and actual needs. Optionally, referring to FIGS. 2-4, the array layer 200 includes a metal layer and an insulating layer arranged in a multi-layer stack. In some embodiments, referring to FIG. 2, a transistor 211 electrically connected to the light-emitting element 300 in the pixel circuit 210 is illustrated as an example, where the transistor 211 includes an active layer 210a, a gate 210b, a source 210c, and a drain 210d, etc. The specific configuration of the transistor 211 may vary, depending on the types of specific metal film layers and insulating film layers in the array layer 200, which are not illustrated in detail here. The light-emitting element 300 is electrically connected to the transistor 211 through a connecting unit 210e, so as to realize the electrical connection between the pixel circuit 210 and the light-emitting element 300.

Optionally, the array layer 200 may further include a driving circuit electrically connected to the pixel circuit, or include a signal line electrically connected to the pixel circuit, and the like, depending on the specific type of the structure in the array layer 200, which is not limited in the present disclosure.

In some embodiments, the display panel 10 further includes a first insulation structure 410, where the first insulation structure 410 and the light-emitting element 30 are both disposed on a side of the array layer 200 away from the substrate 100. The first insulation structure 410 is disposed around at least part of the light-emitting element 300. The first insulation structure 410 surrounding at least part of the light-emitting element 300 may be considered as the first insulation structure 410 surrounding a part of the light-emitting element 300, or surrounding the light-emitting element 300 like a circle. In some embodiments, the first insulation structure 420 may also be disposed between adjacent light-emitting elements 300 to cover redundant metal pads. Based on the specific arrangement position of the first insulation structure 420 around the light-emitting element 300, the configuration of the first insulation structure 420 may be flexibly adjusted. Specifically, referring to FIGS. 2-4, the first insulation structure 410 includes a first insulation subsection 411, and an orthographic projection of the first insulation subsection 411 onto the substrate 100 at least partially overlaps with an orthographic projection of the array layer 200 onto the substrate 100. In other words, along the thickness direction h of the display panel 10, the first insulation subsection 411 at least partially covers the array layer 200. In one example, as shown in FIGS. 2 and 3, along the thickness direction h of the display panel 10, the orthographic projection, of the portion of the array layer 200 not covered by the light-emitting element 300, onto the substrate 100 is greater than the orthographic projection of the first insulation subsection 411 onto the substrate 100. In other words, there is a part of the array layer 200 that is neither covered by the first insulation subsection 411 nor covered by the light-emitting element 300. In another example, as shown in FIG. 4, along the thickness direction h of the display panel 10, the orthographic projection, of the portion of the array layer 200 not covered by the light-emitting element 300, onto the substrate 100 is smaller than the orthographic projection of the first insulation subsection 411 onto the substrate 100. In other words, if the array layer 200 is not covered by the first insulation subsection 411, it is covered by the light-emitting element 300. FIGS. 2-4 show that the positional relationship between the first insulation subsection 411 and the array layer 200 is diverse, which may be adaptively adjusted according to actual needs of the display panel 10.

Specifically, referring to FIGS. 2-4, the first insulation subsection 411 includes a first side surface 411b and a first bottom surface 411a. The orthographic projection of the first bottom surface 411a onto the substrate 100 is located on a side, of the orthographic projection of the first side surface 411b onto the substrate 100, away from the orthographic projection of the light-emitting element 300 onto the substrate 100. In other words, the first bottom surface 411a is farther away from the light-emitting element 300 than the first side surface 411b. In some embodiments, the first side surface 411b includes a first endpoint a1 and a second endpoint a2, where the first endpoint a1 is located on a side of the second endpoint a2 away from the array layer 200. The first bottom surface 411a is connected to the second endpoint a2. In other words, the first bottom surface 411a is connected to the endpoint of the first side surface 411b close to the substrate 100. The first side surface 411b and the first bottom surface 411a in the first insulation subsection 411 together form at least a partial structural surface of a “concave” structure, where the first bottom surface 411a is the bottom surface of the “concave” structure, and the first side surface 411b is a side surface of the “concave” structure. The side surface is close to one side of the light-emitting element 300, so that the first insulation structure 410 surrounds at least part of the light-emitting element 300.

In some embodiments, along the first direction X, the distance between the first endpoint a1 and the light-emitting element 300 is smaller than the distance between the second endpoint a2 and the light-emitting element 300. In other words, the closer a point of the first side surface 411b to the first endpoint a1, the smaller the distance between the point and the light-emitting element 300, and the closer a point of the first side surface 411b to the second endpoint a2, the larger the distance between the point and the light-emitting element 300. This reflects the overall structure tendency of the first side surface 411b, and further reflects the morphology of the first insulation subsection 411 surrounding the light-emitting element 300.

In some embodiments, referring to FIGS. 1, 2, and 4, the first insulation subsection 411 in the display panel 10 is formed by using a light-blocking material, and the first insulation subsection 411 is formed around the light-emitting element 300. This may prevent the color crosstalk between different light-emitting elements 300, and may further prevent the light leakage in the array layer 200, thereby improving the overall display performance of the display panel 10. In some embodiments, referring to FIG. 3, the first bottom surface 411a and the first side surface 411b in the first insulation subsection 411 together form at least a partial structure of a “groove” structure, where the light-blocking material may be filled in the groove surrounded by the first insulation subsection 411 and the adjacent insulation structure. This may also prevent the color crosstalk between different light-emitting elements 300, thereby improving the overall display performance of the display panel 10.

In some embodiments, the adjustment of the morphology of the first insulation subsection 411 may be achieved by adjusting the preparation process of the display panel 10. In the existing technology, the light-emitting element is transferred after the insulation structure is prepared. The insulation structure may be considered as a light-blocking structure, which is configured to prevent crosstalk between adjacent light-emitting elements. When preparing the insulation structure, it is necessary to reserve some space around the light-emitting element to ensure the transfer accuracy when the light-emitting element is transferred and the alignment accuracy of the exposure machine when the insulation structure is prepared. The prepared display panel is not conducive to improving the pixel density of the display panel and cannot further improve the display performance of the display panel. In addition, the side surface of the insulation structure prepared in the existing technology does not cover the side surface of the light-emitting element. In other words, there is a gap between the light-emitting element and the insulation structure. The gap will expose part of the metal layer, reflect the light, and affect the overall display performance. Meanwhile, the insulation structure prepared for a display panel is located between adjacent light-emitting elements, and the general structural shape is a regular trapezoidal structure or a rectangular structure. In other words, the shape and structure of the insulation structure in the existing technology is really limited.

In the preparation process of the display panel 10 provided by the embodiment of the present disclosure, the first insulation structure 410 is prepared after the array layer 200 and the light-emitting element 300 are prepared on the substrate 100. The preparation of the light-emitting element 300 may include transferring the light-emitting element 300 to the side of the array layer 200 away from the substrate 100 by transferring the substrate. Next, an insulation material is applied to the display panel 10, where the insulation material is cured and etched. During the curing and etching processes, a corresponding groove structure is formed. The groove structure may partially correspond to the first bottom surface 411a and the first side surface 411b in the first insulation subsection 411. Here, the formation of the groove structure may be determined based on the properties of the insulation material. For example, referring to FIGS. 2-4, the prepared first insulation structure 410 has a colored solvent before curing. The colored solvent has fluidity. During the curing process, a corresponding slope depression is formed, thereby forming a corresponding first insulation subsection 411, and a corresponding first bottom surface 411a and a first side surface 411b is formed accordingly. It should be noted that the melt flow of the first insulation subsection 411 is similar to a capillary phenomenon. If the flow encounters an obstacle, it will automatically extend upward along the obstacle. Referring to FIGS. 2 and 4, if the colored solvent is a black solvent, the first insulation structure 410 is as shown in the figures. Referring to FIG. 3, if the colored solvent is a white solvent, the first insulation structure 410 is as shown in the figure. In other words, according to different display panels 10, the first insulation structure 410 may be directly prepared by using a light-blocking material, or a light-blocking material may be filled in the first insulation structure 410, to ensure the overall display performance of the display panel 10. By placing the transfer process of the light-emitting element 300 ahead of the preparation process of the insulation structure, the morphology of the first insulation structure 410 may be adjusted. This enables the morphological diversity of the first insulation structure 410, enhances the anti-crosstalk effect of the display panel 10, enhances the diversity of the display panel 10, and ensures the display performance of the display panel 10. In some embodiments, the first side surface 411b of the first insulation subsection 411 in the first insulation structure 410 is attached to the side surface of the light-emitting element 300. In other words, there is no gap between the first insulation structure 410 and the light-emitting element 300, and the first insulation structure 410 may prevent the crosstalk between the side light of the light-emitting elements 300, further ensuring the display performance of the display panel 10. In this way, there is no need to reserve additional space for improving the alignment accuracy of the transfer of the light-emitting element 300, or to reserve additional space to provide the alignment accuracy of the exposure machine during the preparation of the insulation structure. Accordingly, there may be enough space to configure more light-emitting elements 300, which improves the pixel distribution density of the display panel 10, and further improves the overall display performance of the display panel 10.

In summary, an embodiment of the present disclosure provides a display panel, which may help ensure the overall display performance of the display panel by adjusting the shape of the first insulation structure, and the shape adjustment of the first insulation structure may be achieved by adjusting the preparation process during the display panel preparation process.

Continuing to refer to FIGS. 1-3, the first insulation structure 410 further includes a second insulation subsection 412, and the second insulation subsection 412 is located on a side of the first insulation subsection 411 away from the light-emitting element 300.

The second insulation subsection 412 includes a second side surface 412b and a second bottom surface 412a. The second side surface 412b includes a third endpoint a3 and a fourth endpoint a4, where the third endpoint a3 is located on a side of the fourth endpoint a4 away from the array layer 200. Along the first direction X, the distance between the third endpoint a3 and the light-emitting element 300 is greater than the distance between the fourth endpoint a4 and the light-emitting element 300. The second bottom surface 412a is connected to the fourth endpoint a4, and the orthographic projection of the second bottom surface 412a onto the substrate 100 is located on a side, of the orthographic projection of the second side surface 412b onto the substrate 100, close to the orthographic projection of the light-emitting element 300 onto the substrate 100. In some embodiments, the first bottom surface 411a and the second bottom surface 412a are coplanar.

In some embodiments, referring to FIGS. 2 and 3, the first insulation structure 410 includes a first insulation subsection 411 and a second insulation subsection 412. The second insulation subsection 412 is located on a side of the first insulation subsection 411 away from the light-emitting element 300. Exemplarily, referring to FIG. 2, the orthographic projection of the first insulation subsection 411 onto the substrate 100 is b1, the orthographic projection of the light-emitting element 300 onto the substrate 100 is b2, and the orthographic projection of the second insulation subsection 412 onto the substrate 100 is b3. It may be seen from FIG. 2 that along the first direction X, b1 is closer to b2 than b3.

In some embodiments, referring to FIGS. 2 and 3, the second insulation subsection 412 includes a second side surface 412b and a second bottom surface 412a, where the orthographic projection of the second bottom surface 412a onto the substrate 100 is located on a side, of the orthographic projection of the second side surface 412b onto the substrate 100, close to the orthographic projection of the light-emitting element 300 onto the substrate 100. In other words, the second bottom surface 412a is closer to the side of the light-emitting element 300 than the second side surface 412b. In some embodiments, the second side surface 412b includes a third endpoint a3 and a fourth endpoint a4, where the third endpoint a3 is located on a side of the fourth endpoint a4 away from the array layer 200. Meanwhile, the second bottom surface 412a is connected to the fourth endpoint a4. In other words, the second bottom surface 412a is connected to the endpoint of the second side surface 412b close to the substrate 100, so the second side surface 412b and the second bottom surface 412a in the second insulation subsection 412 together form at least part of the structural surface of a “concave” structure, where the second bottom surface 412a is the bottom surface of the “concave” structure, and the second side surface 412b is a side surface of the “concave” structure. It should be noted that the melt flow of the first insulation subsection 411 and the second insulation subsection 412 is similar to a capillary phenomenon. If an obstacle is encountered, the flow will automatically extend upward along the obstacle, thus forming a “concave” structure.

In some embodiments, along the first direction X, the distance between the fourth endpoint a4 and the light-emitting element 300 is smaller than the distance between the third endpoint a3 and the light-emitting element 300. In other words, the closer a point of the second side surface 412b to the third endpoint a3, the greater the distance between the point and the light-emitting element 300. The closer a point of the second side surface 412b to the fourth endpoint a4, the smaller the distance between the point and the light-emitting element 300. This reflects the overall structure tendency of the second side surface 412b.

In some embodiments, the first insulation subsection 411 and the second insulation subsection 412 are connected at the bottom surface. Specifically, the first bottom surface 411a and the second bottom surface 412a are coplanar, so the first insulation subsection 411 and the second insulation subsection 412 together form a complete “groove” structure, where the bottom surface of the “groove” structure is the first bottom surface 411a and the second bottom surface 412a, and the side surfaces of the “groove” structure are the first side surface 411b and the second side surface 412b. Combined with the structure tendency of the first side surface 411b and the second side surface 412b, along the first direction, the width of the “groove” structure close to the array layer 200 is smaller than the width of the “groove” structure away from the array layer 200. This further reflects that the shape adjustment of the first insulation structure 410 is diverse.

In some embodiments, referring to FIGS. 1 and 2, the first insulation subsection 411 and the second insulation subsection 412 both include a light-blocking structure.

Specifically, as shown in FIG. 2, the first insulation structure 410 includes a first insulation subsection 411 and a second insulation subsection 412, where the first insulation subsection 411 includes a light-blocking structure, and the second insulation subsection 412 also includes a light-blocking structure. In other words, the first insulation structure 410 as a whole is a light-blocking structure made of light-blocking material. The light-blocking structure may block the transmission of light. The first insulation structure 410 is arranged around the light-emitting element 300, which may prevent the color crosstalk between light-emitting elements 300 of different colors, thereby ensuring the overall display performance of the display panel 10. In some embodiments, the first insulation subsection 411 and the second insulation subsection 412 are both light-blocking structures. In other words, the first insulation subsection 411 and the second insulation subsection 412 are both made of a light-blocking material, where the first insulation subsection 411 and the second insulation subsection 412 may be considered as an integrated structure.

In some embodiments, before the first insulation structure 410 is cured and etched to form the first insulation subsection 411 and the second insulation subsection 412, the insulation material coated on the side of the array layer 200 or the light-emitting element 300 away from the substrate 100 includes a colored solvent, such as a black solvent. The solid content of the black solvent may be less than 20%, for example, 13.5%. The specific value of solid content is not limited in the disclosure and may be adaptively adjusted according to actual needs. For example, after the insulation material including the colored solvent with a solid content of 13.5% is cured and etched to form the first insulation subsection 411 and the second insulation subsection 412, the morphology of the first insulation subsection 411 and the second insulation subsection 412 may be formed according to the fluidity of the colored solvent when the insulation material is cured. Specifically, the adjustment of the specific morphology of the first insulation subsection 411 and the second insulation subsection 412 may be achieved due to the difference in solid content or by adjusting the process parameters during curing or etching. The embodiments of the present disclosure do not provide details in specific configuration of process parameters.

Continuing to refer to FIGS. 1 and 2, along the thickness direction h of the display panel, the first endpoint a1 is flush with the third endpoint a3.

Specifically, as shown in FIG. 2, along the thickness direction h of the display panel 10, the first endpoint a1 and the third endpoint a3 are flush. In other words, the distance between the first endpoint a1 and the substrate 100 is the same as or similar to the distance between the third endpoint a3 and the substrate 100. On the premise that the first bottom surface 411a and the second bottom surface 412a are flush, the first endpoint a1 and the third endpoint a3 are also flush, then the structural heights of the first insulation subsection 411 and the second insulation subsection 412 are the same. The overall morphology of the first insulation structure 410 is thus more regular, the preparation process of the first insulation structure 410 may be simplified, and the overall preparation cost of the display panel 10 may be reduced.

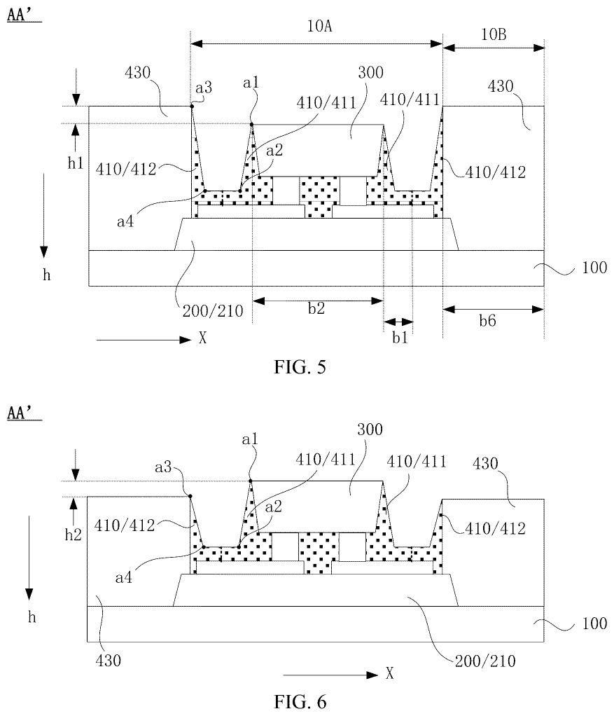

FIG. 5 is a fourth cross-sectional schematic diagram along the section line A-A′ in FIG. 1, and FIG. 6 is a fifth cross-sectional schematic diagram along the section line A-A′ in FIG. 1. Referring to FIGS. 1, 5, and 6, along the thickness direction h of the display panel 10, the first endpoint a1 is disposed on the side of the third endpoint a3 close to the substrate 100, or the third endpoint a3 is disposed on the side of the first endpoint a1 close to the substrate 100.

Specifically, referring to FIGS. 5 and 6, the first insulation subsection 411 and the second insulation subsection 412 in the first insulation structure 410 may be configured differently to ensure different display performances of the display panel 10. Specifically, the different display performances of the display panel 10 may be achieved by adjusting the difference between the third endpoint a3 and the first endpoint a1.

As shown in FIG. 5, along the thickness direction h of the display panel 10, the first endpoint a1 may be located on the side of the third endpoint a3 close to the substrate 100. In other words, the distance between the first endpoint a1 and the substrate 100 is less than the distance between the third endpoint a3 and the substrate 100. In FIG. 5, there is a thickness difference h1 between the first endpoint a1 and the third endpoint a3 in the thickness direction h of the display panel 10. Optionally, if the display panel 10 is a transparent display panel, a transparent insulation material may be provided between adjacent light-emitting elements 300. The transparent insulation material may be used as a display light-transmitting area of the display panel 10, and the area where the light-emitting elements 300 are disposed may be considered as a display area of the display panel 10. It should be noted that when the light of the light-emitting element 300 enters the display light-transmitting area, the light will be reflected in the display light-transmitting area, thereby forming a halo. The first insulation subsection 411 may be arranged to be located on a side close to the light-emitting element 300, and the second insulation subsection 412 may be arranged to be located on a side close to the transparent insulation material. Thus, by adjusting the third endpoint a3 to be higher than the first endpoint a2, it is possible to more effectively prevent light from entering the display light-transmitting area to generate a halo, thereby ensuring the display performance of the display panel 10. In the above, the height of the first side surface 411b in the first insulation subsection 411 is less than the height of the second side surface 412b in the second insulation subsection 412. By setting the height of the second side surface 412b to be higher, it is possible to reduce or even prevent the lateral light of the light-emitting element 300 from entering the display light-transmitting area, thereby minimizing or even preventing the halo formation. Meanwhile, when the height of the first side surface 411b is relatively low, it may save the material of the first insulation subsection 411. In some embodiments, when the height of the first side surface 411b is less than the height of the light-emitting element 300, the effect of a wider viewing angle may be also achieved.

In some embodiments, as shown in FIG. 6, along the thickness direction h of the display panel 10, the first endpoint a1 may be located on a side of the third endpoint a3 away from the substrate 100, and the distance between the first endpoint a1 and the substrate 100 is greater than the distance between the third endpoint a3 and the substrate 100. In FIG. 6, there is a thickness difference h2 between the first endpoint a1 and the third endpoint a3 in the thickness direction h of the display panel 10. Optionally, if the display panel 10 is a transparent display panel, a transparent insulation material may be provided between adjacent light-emitting elements 300. The transparent insulation material may be used as a display light-transmitting area of the display panel 10, while the area where the light-emitting elements 300 are located is considered as a display area of the display panel 10. By adjusting the first endpoint a1 to be higher than the third endpoint a3, when the transparent insulation material is an organic material, the organic material has fluidity during the preparation process. If the third endpoint a3 is higher (i.e., if the height of the transparent insulation material is higher), it is not conducive to the leveling of the transparent insulation material, and the preparation difficulty is increased. Accordingly, when the height of the third endpoint a3 is adjusted to be lower than the height of the first endpoint a1, the difficulty of the manufacturing process of the transparent insulation material may be reduced in the process of manufacturing the display panel 10. In the above, the height of the first side surface 411b in the first insulation subsection 411 is greater than the height of the second side surface 412b in the second insulation subsection 412. In some embodiments, if the first endpoint a1 of the first insulation subsection 411 has the same height as the light-emitting element 300, it may ensure that the light from the side of the light-emitting element 300 is blocked, and crosstalk between different light-emitting elements 300 is prevented, thereby ensuring the overall display performance of the display panel 10. In general, the first insulation structure 410 is configured to prevent crosstalk between the light-emitting elements 300, so it is arranged between adjacent light-emitting elements 300. Meanwhile, in order to ensure the display performance of the display panel 10, the light normally emitted by the light-emitting element 300 should not be blocked by the first insulation structure 410. Therefore, during the preparation of the first insulation structure 410, the height of the first insulation subsection 411 in the first insulation structure 410 may be adjusted to be smaller than the height of the light-emitting element 300, so as to facilitate the realization of the wide viewing angle display effect of the light-emitting elements 300. Meanwhile, the height of the second insulation subsection 412 may be adjusted to block part of the light to prevent crosstalk, or the height of the first insulation subsection 411 is adjusted to be flush with the height of the light-emitting element 300, so as to ensure an optimal anti-crosstalk effect. In some embodiments, during the preparation process, the height of the first insulation subsection 411 in the first insulation structure 410 will not exceed the height of the light-emitting element 300, so as to prevent the first insulation subsection 411 from blocking the normally output light, thereby ensuring the overall display performance of the display panel 10. It should be noted that the array layer 200 is simply shown in FIGS. 5 and 6 to facilitate a clear presentation of the structural schematic diagram of the first insulation structure 410. In the subsequent description, the array layer 200 will be treated similarly, details of which will not be repeated.

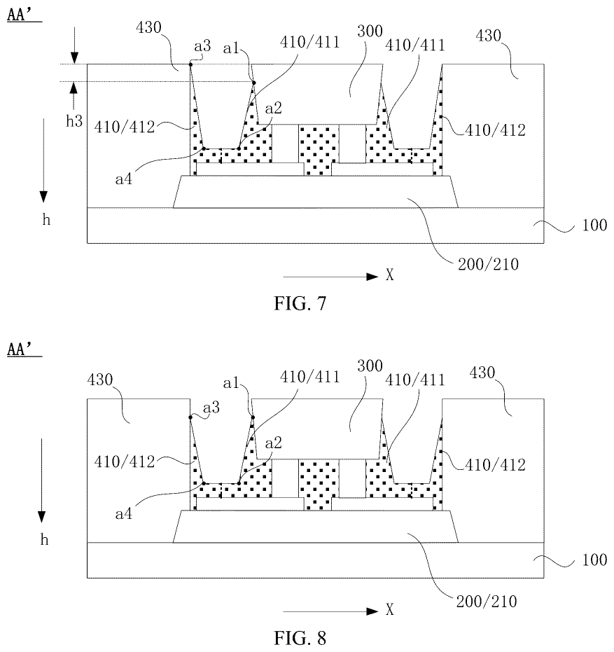

FIG. 7 is a sixth cross-sectional schematic diagram along the section line A-A′ in FIG. 1. Referring to FIGS. 1 and 7, along the thickness direction h of the display panel 10, the first endpoint a1 is disposed on a side of the light-emitting element 300 close to the substrate 100.

In the thickness direction h of the display panel 10, in the first insulation subsection 411, the distance between the first endpoint a1 and the substrate 100 and the distance between the light-emitting element 300 and the substrate 100 may be set differently, thereby improving the display performance of the display panel 10.

Specifically, as shown in FIG. 7, along the thickness direction h of the display panel 10, the first endpoint a1 is disposed on the side of the light-emitting element 300 close to the substrate 100. In other words, the distance between the first endpoint a1 and the substrate 100 is smaller than the distance between the surface of the light-emitting element 300 away from the substrate 100 and the substrate 100. For example, in FIG. 7, the thickness difference between the first endpoint a1 and the surface of the light-emitting element 300 away from the substrate 100 in the thickness direction h of the display panel 10 is h3. In some embodiments, by setting the height of the first side surface 411b in the first insulation subsection 411 to be smaller than the height of the light-emitting element 300, it may ensure that the light-emitting element 300 has a light-emitting effect with a large viewing angle, thereby improving the overall display performance of the display panel 10.

Optionally, referring to FIG. 7, the height of the first endpoint a1 is adjusted to be lower than the height of the light-emitting element 300, so that the light-emitting element 300 may emit light from part of the side of the light-emitting element 300. In other words, the light-emitting element 300 is ensured to have a light-emitting effect with a wide viewing angle. Meanwhile, in order to prevent crosstalk between adjacent light-emitting elements 300, the height of the second side surface 412b in the second insulation subsection 412 may be increased to block the light that may cause crosstalk, thereby ensuring the overall display performance of the display panel 10.

Referring to FIGS. 1, 2, 5, and 7, along the thickness direction h of the display panel 10, the third endpoint a3 is located above a surface of the light-emitting element 300 away from the substrate 100, or the third endpoint a3 is flush with the surface of the light-emitting element 300 away from the substrate 100.

In some embodiments, the second insulation subsection 412 in the first insulation structure 410 may be configured differently to ensure different display performances of the display panel 10. Specifically, different display performances of the display panel 10 may be enhanced by adjusting the difference between the third terminal a3 and the light-emitting element 300.

As shown in FIG. 5, along the thickness direction h of the display panel 10, the third endpoint a3 is located over a surface of the light-emitting element 300 away from the substrate 100, and the distance between the third endpoint a3 and the substrate 100 is greater than the distance between the surface of the light-emitting element 300 away from the substrate 100 and the substrate 100. It should be noted that by adjusting the height of the third endpoint a3 to be larger (e.g., the height of the second insulation subsection 412 is larger), the anti-crosstalk effect may be further improved. In some embodiments, when the height of the first endpoint a1 is adjusted to be smaller than the height of the light-emitting element 300, the display performance of the light-emitting element 300 with a large viewing angle may be guaranteed. When combined with the adjustment of the height of the second insulation subsection 412, the light-emitting element 300 with a large viewing angle may be achieved, and the anti-crosstalk effect may be achieved as well, thereby improving the overall display performance of the display panel 10.

In some embodiments, referring to FIGS. 2 and 7, along the thickness direction h of the display panel 10, the third endpoint a3 is flush with the surface of the light-emitting element 300 away from the substrate 100, and the distance between the third endpoint a3 and the substrate 100 is equal to the distance between the surface of the light-emitting element 300 away from the substrate 100 and the substrate 100. By adjusting the height of the second insulation subsection 412 to be the same as the height of the surface of the light-emitting element 300 away from the substrate 100, the overall regularity of the first insulation structure 410 may be achieved. The first insulation structure 410 may prevent crosstalk between the light-emitting elements 300, and the regularity of the structure may simplify the process of manufacturing the display panel 10 and reduce the process cost of manufacturing the display panel 10.

FIG. 8 is a seventh cross-sectional schematic diagram along the section line A-A′ in FIG. 1. Continuing to refer to FIGS. 1, 2, and 5-8, along the thickness direction h of the display panel 10, the first endpoint a1 is flush with the surface of the light-emitting element 300 away from the substrate 100, or compared to the surface of the light-emitting element 300 away from the substrate 100, the first endpoint a1 is closer to the substrate 100.

In some embodiments, the second insulation subsection 412 in the first insulation structure 410 may be configured differently to ensure different display performances of the display panel 10. For example, the different display performances of the display panel 10 may be achieved by adjusting the difference between the third terminal a3 and the light-emitting element 300.

As shown in FIGS. 2, 5, and 6, along the thickness direction h of the display panel 10, the first endpoint a1 is flush with the surface of the light-emitting element 300 away from the substrate 100, and the distance between the first endpoint a1 and the substrate 100 is equal to the distance between the surface of the light-emitting element 300 away from the substrate 100 and the substrate 100. This means that the height of the first side surface 411b in the first insulation subsection 411 is equal to the height of the surface of the light-emitting element 300 away from the substrate 100. On one hand, when the height of the first insulation structure 410 and the light-emitting element 300 is adjusted to be flush, the first insulation structure 410 blocks the light from the side of the light-emitting element 300 to the maximum extent, thereby preventing the crosstalk of light between adjacent light-emitting elements 300. This then ensures the overall display performance of the display panel 10. On the other hand, when the height of the first insulation structure 410 is adjusted not to exceed the height of the light-emitting element 300, the existence of the first insulation structure 410 will not affect the normal light transmission of the light-emitting element 300, thereby ensuring the overall display performance of the display panel 10.

In some embodiments, referring to FIGS. 7 and 8, along the thickness direction h of the display panel 10, the first endpoint a1 is closer to the substrate 100 than the surface of the light-emitting element 300 away from the substrate 100. In other words, the distance between the first endpoint a1 and the substrate 100 is smaller than the distance between the surface of the light-emitting element 300 away from the substrate 100 and the substrate 100. By adjusting the height of the first insulation subsection 411 to be smaller than the height of the surface of the light-emitting element 300 away from the substrate 100, the first insulation structure 410 is prevented from interfering with the light-emitting effect of the light-emitting element 300, so as to ensure the wide viewing angle display effect of the light-emitting element 300, thereby improving the overall display performance of the display panel 10.

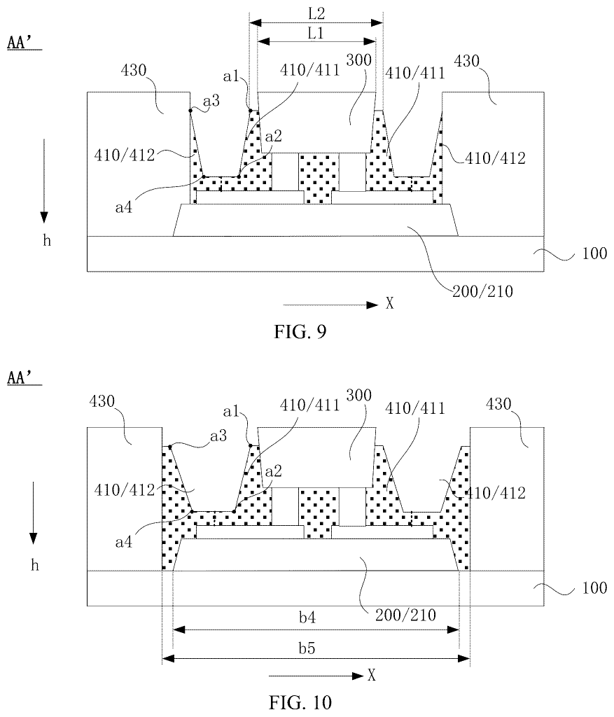

FIG. 9 is an eighth cross-sectional schematic diagram along the section line A-A′ in FIG. 1. Referring to FIGS. 1 and 9, along the first direction X, the width of the light-emitting element 300 is L1, and along the first direction X, the distance between the first endpoints a1 located on two opposite sides of the light-emitting element 300 is L2, where, (L2-L1)>0.

Specifically, the light-emitting element 300 shown in FIG. 9 is a cross-sectional schematic diagram, where the cross-sectional schematic diagram of the light-emitting element 300 may be an inverted trapezoid as shown in FIG. 9, or may be a regular trapezoid, which is not specifically limited in the present disclosure.

In some embodiments, along the first direction X, the width of the light-emitting element 300 is L1, and along the first direction X, the distance between the first endpoints a1 located on two opposite sides of the light-emitting element 300 is L2, where L1 and L2 satisfy (L2-L1)>0. In other words, along the first direction X, the opening of the first insulation subsection 411 on two opposite sides of the light-emitting element 300 may be larger than the upper surface (i.e., the surface of the light-emitting element 300 away from the substrate 100) of the light-emitting element 300. This may allow the light of the light-emitting element 300 to emit as much as possible, thereby improving the light-emitting effect and ensuring the wide viewing angle display effect of the display panel 10.

FIG. 10 is a ninth cross-sectional schematic diagram along the section line A-A′ in FIG. 1. Referring to FIG. 10, the orthographic projection of the first insulation structure 410 onto the substrate 100 covers the orthographic projection of the array layer 200 onto the substrate 100. In FIG. 10, the orthographic projection of the first insulation structure 410 onto the substrate 100 is b5, and the orthographic projection of the array layer 200 onto the substrate 100 is b4. When the first insulation subsection 411 and the second insulation subsection 412 of the first insulation structure 410 are light-blocking structures, along the thickness direction h of the display panel 10, the first insulation structure 410 may cover the entire array layer 200. This not only prevents light crosstalk between different light-emitting elements 300, but also prevents light leakage from the metal structure in the array layer 200, thereby ensuring the overall display performance of the display panel 10.

Continuing to refer to FIGS. 1 and 3, the first insulation structure 410 also includes a first groove 414 and a third insulation subsection 413. The first groove 414 is at least partially surrounded by the first side surface 411b, the first bottom surface 411a, the second side surface 412b, and the second bottom surface 412a, and the third insulation subsection 413 fills the first groove 414.

Specifically, as shown in FIG. 3, the first insulation structure 410 includes a first insulation subsection 411 and a second insulation subsection 412, where the first insulation subsection 411 includes a first side surface 411b and a first bottom surface 411a, and the second insulation subsection 412 includes a second side surface 412b and a second bottom surface 412a. The first groove 414 is formed by the first side surface 411b, the first bottom surface 411a, the second side surface 412b, and the second bottom surface 412a. In other words, the first groove 414 is at least partially composed of the first side surface 411b, the first bottom surface 411a, the second side surface 412b, and the second bottom surface 412a.

In some embodiments, the first insulation structure 410 further includes a third insulation subsection 413, and the third insulation subsection 413 is filled in the first groove 414. The third insulation subsection 413 may ensure the flatness of the overall structure of the display panel 10.

Continuing to refer to FIGS. 1 and 3, the first insulation subsection 411 and/or the second insulation subsection 412 includes a light-reflective structure, and the third insulation subsection 413 includes a light-blocking structure.

Referring to FIG. 3, in the first insulation structure 410, the third insulation subsection 413 includes a light-blocking structure, and the third insulation subsection 413 is disposed in the first groove 414. In other words, the third insulation subsection 413 is disposed between adjacent light-emitting elements 300. The third insulation subsection 413 may prevent light crosstalk between different light-emitting elements 300, thereby ensuring the overall display performance of the display panel 10.

In some embodiments, as shown in FIG. 3, the first insulation subsection 411 and the second insulation subsection 412 may include a light-reflective structure. In other words, the first insulation subsection 411 and the second insulation subsection 412 may increase the light-emitting effect in the light-emitting element 300 due to their reflective feature on the emitted light, thereby ensuring that the light emitted by the light-emitting element 300 has a better light-emitting effect and ensuring the overall display performance of the display panel 10.

In some embodiments, one of the first and second insulation subsections 411/412 and the third insulation subsection 413 may both serve as light-blocking structures. For example, the first insulation subsection 411 and the third insulation subsection 413 serve as light-blocking structures, and the second insulation subsection 412 serves as a light-reflective structure, or the second insulation subsection 412 and the third insulation subsection 413 serve as light-blocking structures, and the first insulation subsection 411 serves as a light-reflective structure, which is not specifically shown in the figure. The specific structural types of the first insulation subsection 411 and the second insulation subsection 412 may be adaptively adjusted according to actual needs for the display panel 10, which is not limited in the present disclosure.

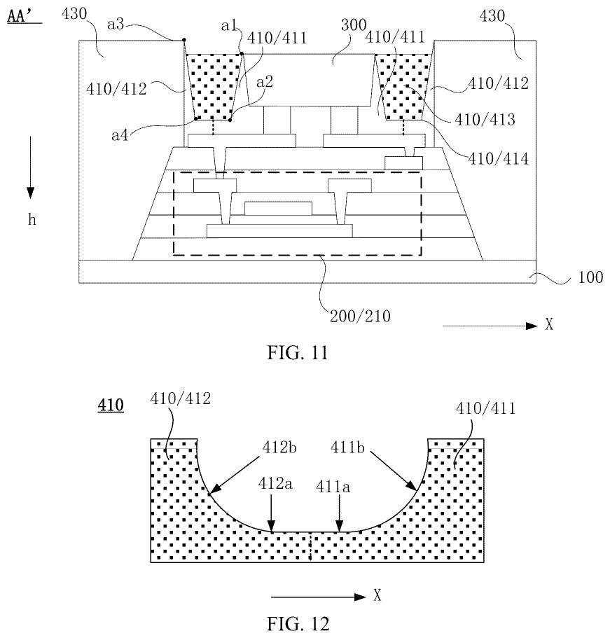

FIG. 11 is the tenth cross-sectional schematic diagram along the section line A-A′ in FIG. 1. Referring to FIGS. 1, 3, and 11, the distance between the surface of the third insulation subsection 413 away from the substrate 10 and the substrate 100 is equal to the distance between the first endpoint a1 and the substrate 100. The distance between the first endpoint a1 and the substrate 100 is less than or equal to the distance between the third endpoint a3 and the substrate 100.

The third insulation subsection 413 is filled in the first groove 414, so the distance between the surface of the third insulation subsection 413 away from the substrate 100 and the substrate does not exceed the distance between the first endpoint a1 and the substrate 100. The distance between the surface of the third insulation subsection 413 away from the substrate 100 and the substrate does not exceed the distance between the third endpoint a3 and the substrate 100.

In some embodiments, referring to FIG. 3, the distance between the surface of the third insulation subsection 413 away from the substrate 100 and the substrate 100 is equal to the distance between the first endpoint a1 and the substrate 100, and the distance between the first endpoint a1 and the substrate 100 is equal to the distance between the third endpoint a3 and the substrate 100, so the distance between the surface of the third insulation subsection 413 away from the substrate 100 and the substrate 100 is equal to the distance between the third endpoint a3 and the substrate 100. That is, when the distance between the surface of the third insulation subsection 413 away from the substrate 100 is equal to the distance between the first endpoint a1 and the substrate 100, the distance between the surface of the third insulation subsection 413 away from the substrate 100 and the substrate is equal to the distance between the third endpoint a3 and the substrate 100, which indicates the flatness of the display panel 10 structure.

In some embodiments, referring to FIG. 11, the distance between the surface of the third insulation subsection 413 away from the substrate 100 and the substrate 100 is equal to the distance between the first endpoint a1 and the substrate 100, and the distance between the first endpoint a1 and the substrate 100 is less than the distance between the third endpoint a3 and the substrate 100. Since the surface of the third insulation subsection 413 away from the substrate 100 should not exceed the first endpoint a1 nor the third endpoint a3, at this point, the distance between the surface of the third insulation subsection 413 away from the substrate 100 and the substrate 100 is less than the distance between the third endpoint a3 and the substrate 100. In this way, it may be ensured that the third insulation subsection 413 filled in the first groove 414 blocks the light crosstalk between the light-emitting elements 300, thereby ensuring the overall display performance of the display panel 10.

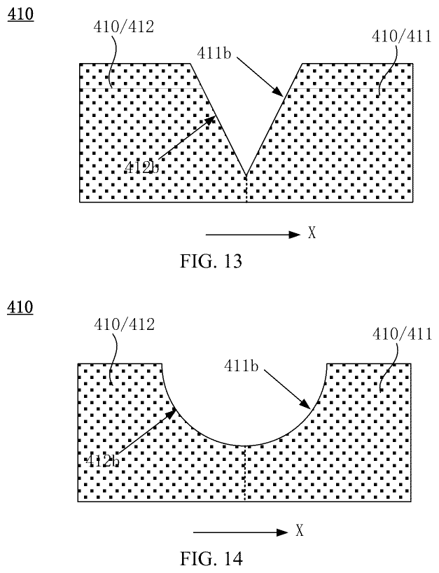

FIG. 12 is a cross-sectional schematic diagram of one first insulation structure, in accordance with an embodiment of the present disclosure, FIG. 13 is a cross-sectional schematic diagram of another first insulation structure, in accordance with an embodiment of the present disclosure, and FIG. 14 is a cross-sectional schematic diagram of another first insulation structure, in accordance with an embodiment of the present disclosure. Referring to FIGS. 12-14, the first side surface 411b includes a plane or a curved surface, and the second side surface 412b includes a plane or a curved surface.

Specifically, there are various ways to adjust the specific morphology of the first insulation structure 410. For example, the first insulation structure 410 includes a first insulation subsection 411 and a second insulation subsection 412. Referring to FIG. 2 and FIG. 13, if the first side surface 411b includes a plane, the first side surface 411b is a straight line in the cross-sectional view. If the second side surface 412b includes a plane, the second side surface 412b is a straight line in the cross-sectional view. Referring to FIG. 12 and FIG. 14, if the first side surface 411b includes a curved surface, the first side surface 411b is a curve in the cross-sectional view. If the second side surface 412b includes a curved surface, the second side surface 412b is a curve in the cross-sectional view.

Continuing to refer to FIGS. 12-14, along the first direction X, the sum of the widths of the first bottom surface 411a and the second bottom surface 412a is W, where W≥0.

In some embodiments, the first bottom surface 411a in the first insulation subsection 411 and the second bottom surface 412a in the second insulation subsection 412 are coplanar, and the structural morphology diversity of the first insulation structure 410 may be achieved by adjusting the sizes of the first bottom surface 411a and the second bottom surface 412a along the first direction X. Exemplarily, referring to FIG. 2 and FIG. 12, the sum of the widths of the first bottom surface 411a and the second bottom surface 412a is W, where W>0. Referring to FIG. 13 and FIG. 14, the sum of the widths of the first bottom surface 411a and the second bottom surface 412a is W, where W=0.

Referring to FIGS. 1-4, the display panel 10 further includes a second insulation structure 420. The second insulation structure 420 is disposed on a side of the light-emitting element 300 close to the array layer 200.

FIGS. 1-4 show that the display panel 10 also includes a second insulation structure 420, which is disposed on a side of the light-emitting element 300 close to the array layer 200. As shown in FIGS. 2 and 4, the second insulation structure 420 may be integrally prepared with the first insulation subsection 411 and the second insulation subsection 412.

Exemplarily, referring to FIG. 2, if the first insulation subsection 411 and the second insulation subsection 412 are light-blocking structures, the second insulation structure 420 is also a light-blocking structure. When the second insulation structure 420 is a light-blocking structure, the light on the side of the light-emitting element 300 close to the substrate 100 may be absorbed to the maximum extent, thereby improving the light leakage condition of the transistor, ensuring the driving effect of the pixel circuit on the light-emitting element 300, and thus ensuring the display performance of the display panel 10.

In some embodiments, referring to FIG. 3, if the first insulation subsection 411 and the second insulation subsection 412 are light-reflective structures, the second insulation structure 420 prepared together with the first insulation subsection 411 and the second insulation subsection 412 is also a light-reflective structure. The light-emitting effect in the light-emitting element 300 may be further increased, thereby ensuring that the light emitted by the light-emitting element 300 has a better emitting effect and the overall display performance of the display panel 10 is ensured.

It should be noted that the cross-sectional views of the display panel 10 provided in FIGS. 4-11 also include the second insulation structure 420, detail of which will not be repeated herein.

Continuing to refer to FIGS. 1-3 and 6-10, the display panel 10 includes a first region 10A and a second region 10B. The second region 10B is located on one side of the first region 10A. The array layer 200 and the light-emitting elements 300 are disposed in the first region 10A. The display panel 10 also includes a third insulation structure 430, which is located in the second region 10B. The orthographic projection of the third insulation structure 430 onto the substrate 100 is located on the side, of the orthographic projection of the first insulation structure 410 onto the substrate 100, away from the orthographic projection of the light-emitting element 300 onto the substrate 100. Along the thickness direction h of the substrate 100, the surface of the third insulation structure 430 away from the substrate 100 is located, on the side of the surface of the light-emitting element 300 away from the substrate 100, close to the substrate 100, or the surface of the third insulation structure 430 away from the substrate 100 is flush with the surface of the light-emitting element 300 away from the substrate 100.

Referring to FIG. 1, the display panel 10 includes a first region 10A and a second region 10B, and the second region 10B is located on one side of the first region 10A. Since the array layer 200 and the light-emitting element 300 are disposed in the first region 10A, the first region 10A may be considered as the display light-emitting region of the display panel 10.

The display panel 10 further includes a third insulation structure 430, and the orthographic projection of the third insulation structure 430 onto the substrate 100 is located on a side, of the orthographic projection of the first insulation structure 410 onto the substrate 100, away from the orthographic projection of the light-emitting element 300 onto the substrate 100. Exemplarily, as shown in FIG. 5, the orthographic projection of the third insulation structure 430 onto the substrate 100 is b6, the orthographic projection of the first insulation structure 410 onto the substrate 100 is b1, and the orthographic projection of the light-emitting element 300 onto the substrate 100 is b2. In some embodiments, the third insulation structure 430 is disposed in the second region 10B. When the third insulation structure 430 is a transparent insulation material, the second region 10B may be considered as a display light-transmitting area in the display panel 10.

In some embodiments, the third insulation structure 430 may be configured in various ways. As shown in FIG. 6, along the thickness direction h of the substrate 100, the surface of the third insulation structure 430 away from the substrate 100 is located, on the side of the surface of the light-emitting element 300 away from the substrate 100, close to the substrate 100. In other words, along the thickness direction h of the display panel 10, the distance between the surface of the third insulation structure 430 away from the substrate 100 and the substrate 100 is smaller than the distance between the surface of the light-emitting element 300 away from the substrate 100 and the substrate 100. This ensures the display performance of the display panel 10 with a wide viewing angle.

Referring to FIGS. 2, 3, and 7-10, the surface of the third insulation structure 430 away from the substrate 100 is flush with the surface of the light-emitting element 300 away from the substrate 100. In other words, along the thickness direction h of the display panel 10, the distance between the surface of the third insulation structure 430 away from the substrate 100 and the substrate 100 is equal to the distance between the surface of the light-emitting element 300 away from the substrate 100 and the substrate 100. This ensures the flatness of the overall structure of the display panel 10.

Referring to FIG. 5, along the thickness direction h of the substrate 100, the surface of the third insulation structure 430 away from the substrate 100 is located, on the side of the surface of the light-emitting element 300 from the substrate 100, away from the substrate 100. In other words, along the thickness direction h of the display panel 10, the distance between the surface of the third insulation structure 430 from the substrate 100 and the substrate 100 is greater than the distance between the surface of the light-emitting element 300 from the substrate 100 and the substrate 100. When the third endpoint a3 of the second side surface 412b in the second insulation subsection 412 is synchronously adjusted in height with the third insulation structure 430, the anti-crosstalk effect of the display panel 10 may be further improved.

Optionally, during the preparation of the display panel 10, the preparation order of the third insulation structure 430 may be placed ahead of the preparation process of the first insulation structure 410. After the array layer 200 is prepared on the substrate 100 and the light-emitting element 300 is transferred, the third insulation structure 430 may be prepared first. If the third insulation structure 430 is a transparent insulation material, the third insulation structure 430 is prepared first, which may ensure the proportion of the transparent area defined by the display panel 10 and improve the light transmittance. Meanwhile, when the third insulation structure 430 is prepared before the first insulation structure 410 is prepared, it may reduce the height difference between the light-emitting element 300 and the upper surface of the array layer 200 when the first insulation structure 410 is prepared, so as to facilitate the formation of the first groove 414 in the first insulation structure 410. In some embodiments, the curing temperature of the third insulation structure 430 during preparation is lower than the melting point of the eutectic layer in the light-emitting element 300. In some embodiments, the refractive index of the third insulation structure 430 may be adjusted to ensure that it is close to the refractive index of an adjacent film layer, thereby ensuring that the light transmittance of the display panel 10 at the third insulation structure 430 is relatively large.

Continuing to refer to FIGS. 1-3 and 5-11, the first insulation structure 410 is in contact with the third insulation structure 430 and/or the first insulation structure 410 is in contact with the light-emitting element 300.

Specifically, referring to FIGS. 1-3 and 5-11, the third insulation structure 430 is in contact with the first insulation structure 410, and the first insulation structure 410 is also in contact with the light-emitting element 300. In some display panels 10, only the first insulation structure 410 and the third insulation structure 430 may be in contact at a location where the light-emitting element 300 is not provided, or the first insulation structure 410 and the light-emitting element 300 may be in contact at a location where the third insulation structure 430 is not provided on the display panel 10.

As shown in FIGS. 1-3 and 5-11, the first insulation structure 410 further includes a second insulation subsection 412, which is disposed on a side of the first insulation subsection 411 away from the light-emitting element 300. The second insulation subsection 412 includes a second side surface 412b and a second bottom surface 412a, the second side surface 412b includes a third endpoint a3 and a fourth endpoint a4, and the third endpoint a3 is located on a side of the fourth endpoint a4 away from the array layer 200. Along the first direction X, the distance between the third endpoint a3 and the light-emitting element 300 is greater than the distance between the fourth endpoint a4 and the light-emitting element 300. The second bottom surface 412b is connected to the fourth endpoint a4. The orthographic projection of the second bottom surface 412a onto the substrate 100 is located on a side, of the orthographic projection of the second side surface 412b onto the substrate 100, close to the orthographic projection of the light-emitting element 300 onto the substrate 100. The first bottom surface 411a and the second bottom surface 412a are coplanar. Along the thickness direction h of the substrate 100, the third endpoint a3 is disposed on a side, of the surface of the third insulation structure 430 away from the substrate 100, close to the substrate 100, or the third endpoint a3 is flush with the surface of the third insulation structure 430 away from the substrate 100.

In some embodiments, the display panel 10 includes a first insulation structure 410 and a third insulation structure 430, and the orthographic projection of the third insulation structure 430 onto the substrate 100 is located on a side of the orthographic projection of the first insulation structure 410 onto the substrate 100 away from the orthographic projection of the light-emitting element 300 onto the substrate 100. The first insulation structure 410 includes a first insulation subsection 411 and a second insulation subsection 412. Different display performances of the display panel 10 may be achieved by adjusting the relative position relationship between the first insulation structure 410 and the third insulation structure 430.

Specifically, referring to FIGS. 8-10, the third endpoint a3 is located on the side, of the surface of the third insulation structure 430 away from the substrate 100, close to the substrate 100. In other words, along the thickness direction h of the display panel 10, the distance between the surface of the third insulation structure 430 away from the substrate 100 and the substrate 100 is greater than the distance between the third endpoint a3 and the substrate 100. That is, the height of the third insulation structure 430 may be flush with the height of the surface of the light-emitting element 300 away from the substrate 100, so that the third insulation structure 430 may ensure the flatness of the overall structure of the display panel 10. The height of the third endpoint a3 may be considered as the configured height of the first insulation structure 410, which is lower than the height of the third insulation structure 430. The first insulation structure 410 will not affect the overall flatness of the display panel 10. Meanwhile, the height of the third insulation structure 430 is larger than the height of the second insulation subsection 412, which is convenient for the preparation of the first insulation structure 410 during the preparation of the display panel 10.

In some embodiments, referring to FIGS. 2, 3, 5-7, and 11, the third endpoint a3 is flush with the surface of the third insulation structure 430 away from the substrate 100.

In some embodiments, along the thickness direction h of the display panel 10, the distance between the surface of the third insulation structure 430 away from the substrate 100 and the substrate 100 is equal to the distance between the third endpoint a3 and the substrate 100. That is, the height of the third insulation structure 430 may be flush with the height of the surface of the light-emitting element 300 away from the substrate 100, so that the third insulation structure 430 may ensure the flatness of the overall structure of the display panel 10. The height of the third endpoint a3 may be considered as the configured height of the first insulation structure 410, which is also equal to the height of the third insulation structure 430. The first insulation structure 410 will not affect the overall flatness of the display panel 10. In some embodiments, the maximum height that the second insulation subsection 412 may reach is the height of the third insulation structure 430, so when the height of the second insulation subsection 412 is equal to the height of the third insulation structure 430, it may more effectively prevent the light crosstalk between different light-emitting elements 300, thereby ensuring the overall display performance of the display panel 10.

Referring to FIGS. 1 and 4, the first insulation subsection 411 includes a light-blocking structure.

In some embodiments, referring to FIGS. 1 and 4 and further referring to FIG. 2, the first insulation structure 410 includes a first insulation subsection 411, where the first insulation subsection 411 includes a light-blocking structure. In other words, the first insulation structure 410 as a whole is a light-blocking structure made of a light-blocking material. The light-blocking structure may block the transmission of light. The first insulation subsection 411 is disposed around the light-emitting element 300, which may prevent the color crosstalk between light-emitting elements 300 of different colors, thereby ensuring the overall display performance of the display panel 10.

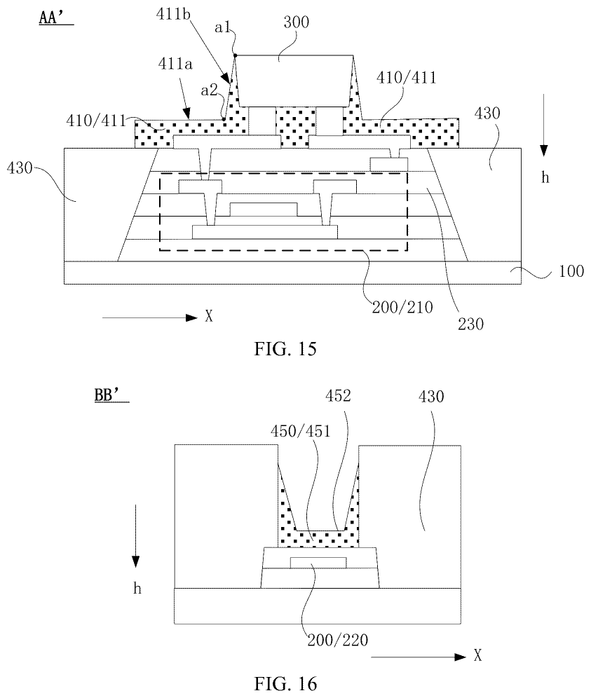

FIG. 15 is an eleventh cross-sectional schematic diagram along the section line A-A′ in FIG. 1. Referring to FIGS. 1 and 15, the first insulation subsection 411 serves as a light-blocking structure, and the orthographic projection of the first insulation subsection 411 onto the substrate 100 covers the orthographic projection of the array layer 200 onto the substrate 100. Along the thickness direction h of the display panel 10, the first insulation subsection 411 and the light-emitting element 300 may cover the entire array layer 200, and the light-emitting element 300 is used for light-emitting display. While the first insulation subsection 411 prevents light crosstalk between different light-emitting elements 300, the metal structure in the array layer 200 covered by the first insulation subsection 411 prevents light leakage, thereby ensuring the overall display performance of the display panel 10.

Referring to FIGS. 1, 4, and 15, the display panel 10 includes a first region 10A and a second region 10B, where the second region 10B is located on one side of the first region 10A. The array layer 200 and the light-emitting element 300 are disposed in the first region 10A. The display panel 10 also includes a fourth insulation structure 440, where the fourth insulation structure 440 is disposed in the second region 10B. The orthographic projection of the fourth insulation structure 440 onto the substrate 100 is located on a side, of the orthographic projection of the first insulation structure 410 onto the substrate 100, away from the orthographic projection of the light-emitting element 300 onto the substrate 100. The array layer 200 also includes a planarization layer 230. The fourth insulation structure 440 and the planarization layer 230 are on the same layer.

Referring to FIG. 1, the display panel 10 includes a first area 10A and a second area 10B. The first area 10A may be considered as a display light-emitting area of the display panel 10, and the second area 10B may be considered as a display light-transmitting area of the display panel 10.

In some embodiments, referring to FIGS. 4 and 15, the display panel 10 further includes a fourth insulation structure 440, and the orthographic projection of the fourth insulation structure 440 onto the substrate 100 is located on a side of the orthographic projection of the first insulation structure 410 onto the substrate 100 away from the orthographic projection of the light-emitting element 300 onto the substrate 100. In some embodiments, the fourth insulation structure 440 is disposed in the second region 10B. When the fourth insulation structure 440 is a transparent insulation material, the overall light transmittance of the display panel 10 may be guaranteed.

The array layer 200 includes a planarization layer 230, and the planarization layer 230 may ensure the flatness of the overall structure in the array layer 200. The planarization layer 230 may be located between the metal film layers, or on the side of the metal film layers away from the substrate 100. Not all film layers are marked one by one in FIGS. 4 and 15. In some embodiments, the fourth insulation structure 440 may be disposed in the same layer as the planarization layer 230. In the preparation process of the display panel 10, the fourth insulation structure 440 and the planarization layer 230 are prepared synchronously using the same process, which may save process steps. In this way, the overall film thickness of the display panel 10 may be ensured to be thin, which is conducive to realizing the thin design of the display panel 10.

Optionally, the planarization layer 230 located on the side of the metal film layers, in the array layer 200, away from the substrate 100 may be prepared by using a transparent insulation material. The fourth insulation structure 440 may be prepared simultaneously with the transparent planarization layer 230, thereby reducing the preparation process of the display panel 10 and reducing the preparation cost of the display panel 10.

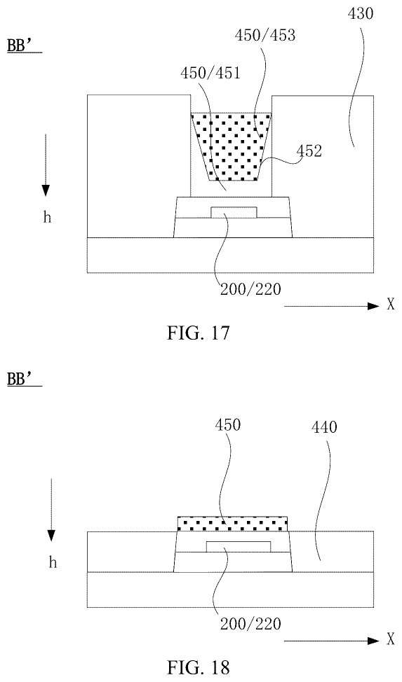

FIG. 16 is a first cross-sectional schematic diagram along the section line B-B′ in FIG. 1, FIG. 17 is a second cross-sectional schematic diagram along the section line B-B′ in FIG. 1, and FIG. 18 is a third cross-sectional schematic diagram along the section line B-B′ in FIG. 1. Referring to FIGS. 1 and 16-18, the array layer 200 also includes a signal line 220, and the display panel 10 also includes a fifth insulation structure 450. The fifth insulation structure 450 is disposed on the side of the signal line 220 away from the substrate 100.

Specifically, the array layer 200 also includes a signal line 220, which may be considered as a signal line electrically connected to the pixel circuit 210, such as a data signal line, a scanning signal line or a power signal line, etc., which is not limited in the present disclosure. In some embodiments, referring to FIGS. 16-18, the display panel 10 also includes a fifth insulation structure 450, which is located on the side of the signal line 220 away from the substrate 100. In other words, the fifth insulation structure 450 is configured to cover the signal line 220. The signal line 220 is made of metal material. The routing of the signal line 220 should prevent the metal material from affecting part of the light, thereby ensuring the overall display performance of the display panel 10.

Exemplarily, referring to FIGS. 16 and 17, the fifth insulation structure 450 includes a groove structure that covers and shields the signal line 220. Referring to FIG. 18, the fifth insulation structure 450 includes a light-shielding insulating film layer that covers and shields the signal line 220.

Continuing to refer to FIGS. 16 and 17, the fifth insulation structure 450 includes a fourth insulation subsection 451. The fourth insulation subsection 451 includes a second groove 452. The second groove 452 partially penetrates the fourth insulation subsection 451.

Specifically, referring to FIGS. 16 and 17, the fifth insulation structure 450 includes a fourth insulation subsection 451, and the fourth insulation subsection 451 includes a second groove 452.

Specifically, before the fifth insulation structure 450 is cured and etched to form the fourth insulation subsection 451, the insulation material coated on the side of the signal line 220 away from the substrate 100 includes a colored solvent, such as a black solvent. The solid content of the black solvent may be less than 20%, for example, 13.5%. There is no limitation on the specific solid content value included therein, which may be adaptively adjusted according to actual needs. For example, after the insulation material including the colored solvent with a solid content of 13.5% is cured and etched, a second groove 452 is formed. The morphology of the second groove 452 may be formed according to the fluidity of the colored solvent when the insulation material is cured. Specifically, the adjustment of the specific morphology of the second groove 452 may be achieved by adjusting the difference in solid content or the process parameters during curing or etching. The present disclosure does not provide specific examples for specific parameter settings.

Continuing to refer to FIG. 16, the fourth insulation subsection 451 includes a light-blocking structure.

In some embodiments, referring to FIG. 16, the fourth insulation subsection 451 includes a light-blocking structure. In other words, the fourth insulation subsection 451 is a light-blocking structure made of a light-blocking material. The light-blocking structure may block the transmission of light. The fourth insulation subsection 451 is configured to cover the signal line 220, which may prevent the metal wire routing from affecting part of the light, thereby ensuring the overall display performance of the display panel 10.

Continuing to refer to FIG. 17, the fifth insulation structure 450 further includes a fifth insulation subsection 453, and the fifth insulation subsection 453 fills the second groove 452.

In some embodiments, referring to FIG. 17, the fifth insulation structure 450 further includes a fifth insulation subsection 453. The fifth insulation subsection 453 is filled in the second groove 452. The fifth insulation subsection 453 may ensure the overall flatness of the display panel 10.

Continuing to refer to FIG. 17, the fourth insulation subsection 451 includes a light-reflective structure, and the fifth insulation subsection 453 includes a light-blocking structure.

Specifically, referring to FIG. 17, the fifth insulation subsection 453 as a whole is a light-blocking structure made of a light-blocking material. The light-blocking structure may block the transmission of light. The fifth insulation subsection 453 is configured to cover the signal line 220, which may prevent the metal wire routing from affecting part of the light, thereby ensuring the overall display performance of the display panel 10. In some embodiments, referring to FIG. 17, the fourth insulation subsection 451 may also include a light-reflective structure. Since the fifth insulation subsection 453 with a light-blocking effect is filled in the second groove 452, the material selection of the fourth insulation subsection 451 is flexible.

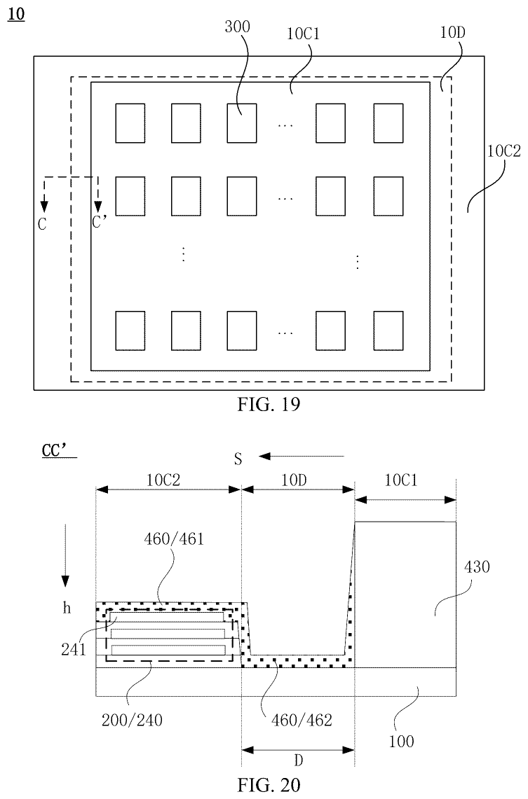

FIG. 19 is a schematic structural diagram of a second display panel, in accordance with an embodiment of the present disclosure, and FIG. 20 is a schematic diagram of a first cross-section along the section line C-C′ in FIG. 19. Referring to FIGS. 19 and 20, the display panel 10 includes a first area 10C1 and a second area 10C2, and the first area 10C1 is located on one side of the second area 10C2. The array layer 200 includes a pixel circuit and a driving circuit 240, and the pixel circuit is electrically connected to the driving circuit 240 and the light-emitting element respectively. The pixel circuit is disposed in the first area 10C1, and the driving circuit 240 is disposed in the second area 10C2. The display panel 10 also includes a transition area 10D, and the transition area 10D is located between the first area 10C1 and the second area 10C2. The display panel 10 also includes a sixth insulation structure 460, and the sixth insulation structure 460 includes a first light-blocking section 461 and a second light-blocking section 462. The first light-blocking subsection 461 is disposed in the second area 10C2, and the first light-blocking subsection 461 is disposed on a side of the driving circuit 240 away from the substrate 100. The second light-blocking section 462 is disposed in the transition area 10D, and the second light-blocking section 462 and the first light-blocking subsection 461 are located on the same side of the substrate 100.

Specifically, the array layer 200 includes a pixel circuit and a driving circuit 240. The pixel circuit is electrically connected to the driving circuit 240, and the driving circuit 240 may transmit a scanning signal to the pixel circuit. The pixel circuit is also electrically connected to the light-emitting element, and the pixel circuit drives the light-emitting element to perform light-emitting display, thereby realizing the overall display performance of the display panel 10.

In some embodiments, referring to FIG. 19, the display panel 10 includes a first area C1, a second area C2, and a transition area 10D. The first area C1 is located on one side of the second area C2, and the transition area 10D is located between the first area 10C1 and the second area 10C2. Specifically, referring to FIG. 20, the pixel circuit is disposed in the first area 10C1, and the driving circuit 240 is disposed in the second area 10C2, where the driving circuit 240 is shown in FIG. 20 as several metal wire routing layers. The specific film layer structure of the driving circuit 240 is not described in detail in the embodiment of the present disclosure. The pixel circuit is not shown in FIG. 20, and only the third insulation structure 430 is shown at the first area C1, and it may also be shown as the fourth insulation structure 440, specific detail of which is not provided in the present disclosure.

In some embodiments, referring to FIG. 20, the display panel 10 further includes a sixth insulation structure 460, which includes a second light-blocking subsection 462 located in the transition region 10D and a first light-blocking subsection 461 located in the second region C2. The first light-blocking subsection 461 is disposed on the side of the drive circuit 240 away from the substrate 100, and the second light-blocking subsection 462 and the first light-blocking subsection 461 are located on the same side of the substrate 100. The first light-blocking subsection 461 and the second light-blocking subsection 462 may be light-blocking structures. In some embodiments, the first light-blocking subsection 461 and the second light-blocking subsection 462 are integrally prepared. By providing the sixth insulation structure 460, the situation where light leakage occurs in the drive circuit 220 may be prevented. In addition, the sixth insulation structure 460 covers the second region C2 and the transition region 10D, which is conducive to improving the overall structural stability of the display panel 10.

Continuing to refer to FIGS. 19 and 20, along the direction from the first region 10C1 to the second region 10C2, the width of the transition region 10D is D, where D≤40 μm.

In some embodiments, referring to FIGS. 19 and 20, along the direction S from the first area 10C1 to the second area 10C2, the width of the transition area 10D is less than or equal to 40 μm, so that the width of the transition area 10D may be ensured to be small. If the second area 10C2 is a non-display area, the narrow frame design of the display panel 10 is facilitated by reducing the size of the transition area 10D. If the second area 10C2 and the transition area 10D are display areas like the first area 10C1 (e.g., light-emitting elements are also arranged in the second area 10C2 and the transition area 10D), the light-emitting elements disposed in the second area 10C2 and the transition area 10D are electrically connected to the pixel circuits in the first area 10C1 through the connecting wires. In other words, the light-emitting elements disposed in the second area 10C2 and the transition area 10D do not overlap with pixel circuits in the thickness direction h of the display panel, which facilitates the display panel to achieve a borderless display performance. In some embodiments, during the preparation of the sixth insulation structure 460, the space in the direction from the first area 10C1 to the second area 10C2 is smaller, so the preparation liquid level of the second light-blocking portion 462 in the sixth insulation structure 460 may be shortened, thereby effectively weakening the tendency of film peeling in the second area 10C2, thereby ensuring the overall structural stability of the display panel 10.

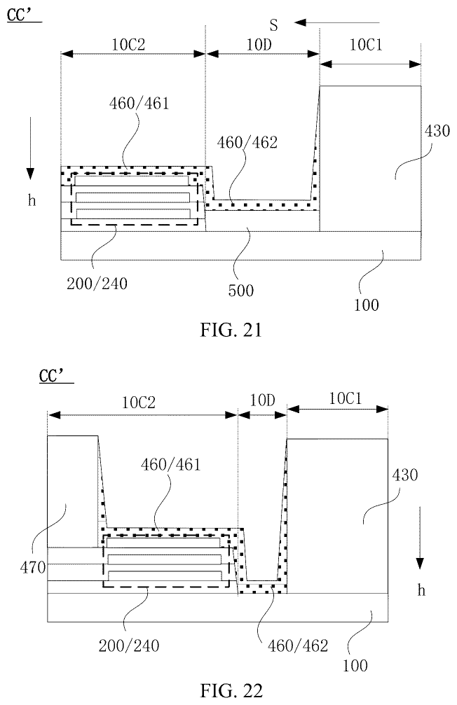

FIG. 21 is a second cross-sectional schematic diagram along the section line C-C′ in FIG. 1. Referring to FIG. 21, the display panel 10 also includes an insulating layer structure and/or a conductive structure (shown as 500 in the figure), where the insulating layer structure and/or the conductive structure are disposed on the side of the second light-blocking portion 462 close to the substrate 100.

In some embodiments, referring to FIG. 21, the display panel 10 may also include an insulating layer structure and/or a conductive structure (the structure indicated by 500 in FIG. 21). The insulating layer structure and/or the conductive structure are disposed on the side of the second light-blocking section 462 close to the substrate 100. By configuring the insulating layer structure and/or the conductive structure, the position of the second light-blocking section 462 may be raised compared to when there is no insulating layer structure and/or the conductive structure, thereby reducing the height difference between the first light-blocking subsection 461 and the second light-blocking section 462. This ensures that the preparation of the sixth insulation structure 460 is more convenient and the structure of the sixth insulation structure 460 is more stable.

In some embodiments, the structure added on the side of the second light-blocking portion 462 close to the substrate 100 may be an insulating layer structure, or a conductive structure, or may include both an insulating layer structure and a conductive structure, which is not specifically limited in the present disclosure.

FIG. 22 is a third cross-sectional schematic diagram along the section line C-C′ in FIG. 19. Referring to FIG. 22, the display panel 10 also includes a seventh insulation structure 470, and the seventh insulation structure 470 is disposed on the side of the first light-blocking subsection 461 away from the second light-blocking section 462, and the seventh insulation structure 470 is disposed on the side of the driving circuit 240 away from the substrate 100.

In some embodiments, referring to FIG. 22, the display panel 10 further includes a seventh insulation structure 470, which is disposed on a side of the driving circuit 240 away from the substrate 100, and is disposed on a side of the first light-blocking subsection 461 away from the second light-blocking subsection 462 in a direction from the first area 10C1 to the second area 10C2. In conjunction with FIG. 22, if the first area 10C1 includes the third insulation structure 430, the seventh insulation structure 470 and the third insulation structure 430 together provide a fixed space for setting the sixth insulation structure 460. It should be noted that the seventh insulation structure 470 may be considered as a “blocking wall.” The seventh insulation structure 470 and the third insulation structure 430 together increase the adhesion force on two opposite sides of the sixth insulation structure 460, ensuring the structural stability of the sixth insulation structure 460, thereby improving the overall structural stability of the display panel 10.

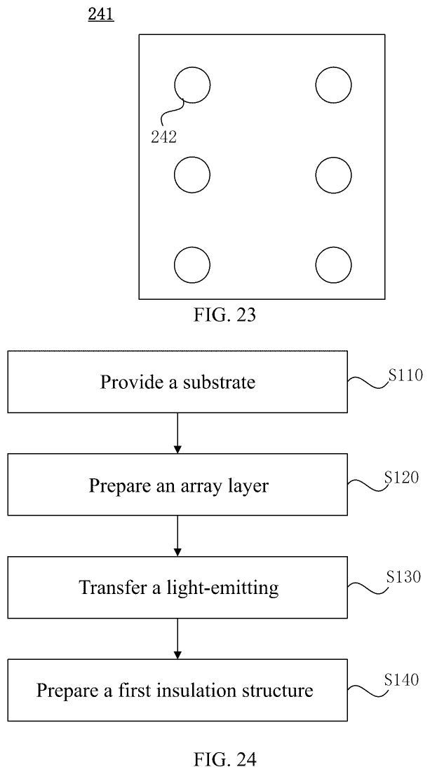

FIG. 23 is a top view of a first metal wire routing section, in accordance with an embodiment of the present disclosure. Referring to FIGS. 20 and 23, the driving circuit 240 includes multiple metal wire routing layers, and the metal wire routing layers include a first metal wire routing section 241. The first metal wire routing section 241 is disposed on the side of the first light-blocking subsection 461 close to the substrate 100, and the first light-blocking subsection 461 covers the first metal wire routing section 241. The first metal wire routing section 241 includes at least one hollow unit 242.

Specifically, referring to FIG. 20, the driving circuit 240 includes a plurality of metal wire routing layers, and the specific number and position of the metal wire routing layers are not limited in the present disclosure. In some embodiments, the metal wire routing layers include a first metal wire routing section 241, and the first metal wire routing section 241 is disposed on the side of the first light-blocking subsection 461 close to the substrate 100. In other words, the first metal wire routing section 241 is the metal wire routing layer on the side of the driving circuit 240 away from the substrate 100, and the first metal wire routing section 241 is in contact with the first light-blocking subsection 461. No other insulating film layer or metal film layer is disposed between the first metal wire routing section 241 and the first light-blocking subsection 461.

In some embodiments, referring to FIG. 23, the first metal wire routing section 241 includes at least one hollow unit 242, and the number and shape of the hollow units 242 are not specifically limited in the disclosure. FIG. 23 takes a configuration that the first metal wire routing section 241 includes six circular hollow units 242 as an example for illustration. When the first metal wire routing section 241 includes multiple hollow units 242, the arrangement of the multiple hollow units 242 is not specifically limited in the disclosure.

In some embodiments, the first metal wire routing section 241 is disposed on a side of an insulating layer of the array layer 200 away from the substrate 100, and the first light-blocking subsection 461 is disposed on a side of the first metal wire routing section 241 away from the substrate 100. When the first metal wire routing section 241 includes at least one hollow unit 242, when preparing the first light-blocking subsection 461, the first light-blocking subsection 461 may be deposited at the hollow unit 242 and contact an insulating layer in the array layer 200. It should be noted that by setting the hollow unit 242, the contact area between the first light-blocking subsection 461 and the insulating layer in the array layer 200 may be increased, so as to ensure a more stable setting of the sixth insulation structure 460, reduce the tendency of peeling between the film layers, and thus ensure the overall structural stability of the display panel 10.

Based on the same inventive concept, an embodiment of the present disclosure further provides a method for preparing a display panel. FIG. 24 is a schematic diagram of a preparation process of a first display panel, in accordance with an embodiment of the present disclosure. Referring to FIG. 24, the preparation process includes:

S110: Provide a substrate.

Exemplarily, the provided substrate may be a rigid substrate, such as glass, or a flexible substrate. The embodiment of the present disclosure does not limit the type of substrate.

S120: Prepare an array layer.

In some embodiments, an array layer is prepared on one side of the substrate. The array layer may include a pixel circuit. The pixel circuit is electrically connected to a subsequently transferred light-emitting element, and is configured to drive the light-emitting element to perform light-emitting display, thereby realizing the display function of the display panel.

Optionally, the array layer is illustrated by taking a pixel circuit as an example, and the pixel circuit includes at least one transistor. Based on the type and number of specific transistors, the type of the pixel circuit in the present disclosure is not limited, and may be adaptively adjusted according to actual needs. Optionally, the array layer includes a multi-layer stacked metal layer and an insulating layer. In some embodiments, the transistor includes an active layer, a gate, a source, and a drain, etc. The types of specific metal film layers and insulating film layer(s) in the array layer are not specifically illustrated.

Optionally, the array layer may further include a driving circuit electrically connected to the pixel circuit, or include a signal line electrically connected to the pixel circuit, and so on, depending on the specific type of structure in the array layer, which is not limited in the disclosure.

S130: Transfer a light-emitting element.

Specifically, the light-emitting element may be prepared on a transfer substrate in advance, and the light-emitting element may be transferred to a side of the array layer away from the substrate by moving the transfer substrate with the light-emitting element to the substrate. In some embodiments, the light-emitting element may include a red light-emitting element, a blue light-emitting element, a green light-emitting element, etc. The pixel circuit(s) drives the light-emitting elements of different colors to emit light for display, thereby realizing the color display performance of the display panel.

S140: Prepare a first insulation structure.

In some embodiments, a first insulation structure is prepared, where the first insulation structure and the light-emitting element are both located on a side of the array layer away from the substrate. The first insulation structure is disposed around at least part of the light-emitting element. Specifically, the first insulation structure includes a first insulation subsection, and along the thickness direction of the display panel, the orthographic projection of the first insulation subsection onto the substrate overlaps at least partially with the orthographic projection of the array layer onto the substrate. In other words, the first insulation subsection covers at least part of the array layer. For example, along the thickness direction of the display panel, the orthographic projection, of the portion of the array layer not covered by the light-emitting element, onto the substrate is greater than the orthographic projection of the first insulation subsection onto the substrate. In other words, there is a part of the array layer that is neither covered by the first insulation subsection nor by the light-emitting element. Alternatively, along the thickness direction of the display panel, the orthographic projection, of the portion of the array layer not covered by the light-emitting element, onto the substrate is less than the orthographic projection of the first insulation subsection onto the substrate. In other words, if the array layer is not covered by the first insulation subsection, it is covered by the light-emitting element. It can be seen that the positional relationship between the first insulation subsection and the array layer is diverse, and may be adaptively adjusted according to actual needs of the display panel.

In some embodiments, the first insulation subsection includes a first side surface and a first bottom surface, where the orthographic projection of the first bottom surface onto the substrate is located on the side, of the orthographic projection of the first side surface onto the substrate, away from the orthographic projection of the light-emitting element onto the substrate. In other words, the first bottom surface is on the side away from the light-emitting element compared to the first side surface. In some embodiments, the first side surface includes a first endpoint and a second endpoint, where the first endpoint is located on the side of the second endpoint away from the array layer. Meanwhile, the first bottom surface is connected to the second endpoint. In other words, the first bottom surface is connected to the endpoint of the first side surface close to the substrate. The first side surface and the first bottom surface in the first insulation subsection tougher form at least part of the structural surface of a “concave” structure, where the first bottom surface is the bottom surface of the “concave” structure, while the first side surface is the side surface of the “concave” structure. The side surface is close to the side of the light-emitting element, so that the first insulation structure surrounds at least part of the light-emitting element. When discussing the first insulation structure surrounding at least part of the light-emitting element, it may mean that the first insulation structure surrounds a part of a light-emitting element, or surrounds the light-emitting element like a circle.

In some embodiments, along the first direction, the distance between the first endpoint and the light-emitting element is smaller than the distance between the second endpoint and the light-emitting element. In other words, the closer a point of the first side surface to the first endpoint, the smaller the distance between the point of the first side surface and the light-emitting element. The closer a point of the first side surface to the second endpoint, the larger the distance between the point of the first side surface and the light-emitting element. This reflects the overall structure tendency of the first side surface, and further reflects the morphology of the first insulation subsection surrounding the light-emitting element.

In some embodiments, the first insulation subsection in the display panel is made of a light-blocking material, and the first insulation subsection is disposed around the light-emitting element, which may prevent color crosstalk between different light-emitting elements, and may further prevent light leakage in the array layer, thereby improving the overall display performance of the display panel. In some embodiments, the first bottom surface and the first side surface in the first insulation subsection together form at least a partial structure of a “groove” structure, and the light-blocking material may be filled in the groove surrounded by the first insulation subsection and the adjacent insulation structure(s). This may also prevent color crosstalk between different light-emitting elements and improve the overall display performance of the display panel.

In some embodiments, in the preparation process of the display panel provided by the embodiment of the present disclosure, after the array layer and the light-emitting element are prepared on the substrate (the preparation of the light-emitting element may be achieved by transferring the light-emitting element to the side of the array layer away from the substrate through the transfer substrate), the first insulation structure is prepared. Specifically, an insulation material is applied to the display panel, and is cured and etched. During the curing process, a corresponding groove structure will be formed, and the groove structure may partially correspond to the first bottom surface and the first side surface in the first insulation subsection. In some embodiments, the formation of the groove structure may be determined according to the properties of the insulation material. For example, the prepared first insulation structure has a colored solvent before curing, and the colored solvent has fluidity. During the curing process, a corresponding slope depression will be formed. After etching the first insulation structure, the corresponding first insulation subsection is formed, and the corresponding first bottom surface and the first side surface are formed accordingly. It should be noted that when preparing the first insulation structure, the melt flow of the first insulation subsection is similar to a capillary phenomenon. If an obstacle is encountered, the flow will automatically extend upward along the obstacle, so that a groove structure may be formed. According to various display panels of the disclosure, the first insulation structure may be directly prepared with a light-blocking material, or the light-blocking material may be filled in the first insulation structure to ensure the overall display performance of the display panel. By placing the transfer process of the light-emitting element before the preparation process of the insulation structure, the morphology of the first insulation structure may be adjusted to reflect the morphology diversity of the first insulation structure. This improves the anti-crosstalk effect of the display panel, improves the diversity of the display panel, and ensures the display performance of the display panel. In some embodiments, the first side of the first insulation subsection in the first insulation structure is attached to the side of the light-emitting element. In other words, there is no gap between the first insulation structure and the light-emitting element. The first insulation structure may prevent the crosstalk between the side light of the light-emitting elements, further ensuring the display performance of the display panel. Meanwhile, there is no need to reserve additional space to improve the alignment accuracy of the light-emitting element transfer, or to reserve additional space to provide the alignment accuracy of the exposure machine during the preparation of the insulation structure. There may be enough space to configure more light-emitting elements, thereby improving the pixel distribution density of the display panel, and further improving the overall display performance of the display panel.

In summary, an embodiment of the present disclosure provides a method for preparing a display panel. By adjusting the preparation of the first insulation structure after the transfer of the light-emitting element, the shape of the first insulation structure may be adjusted, which may be beneficial to ensuring the overall display performance of the display panel. The shape adjustment of the first insulation structure may be achieved by adjusting the preparation process during the preparation of the display panel.

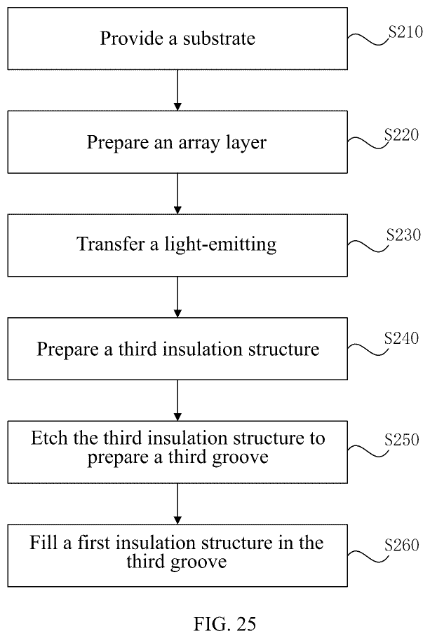

FIG. 25 is a schematic diagram of another preparation process of a first display panel, in accordance with an embodiment of the present disclosure. Referring to FIG. 25, the preparation process includes:

S210: Provide a substrate.

S220: Prepare an array layer.

S230: Transfer a light-emitting element.

S240: Prepare a third insulation structure.

In some embodiments, after preparing the array layer on the substrate and transferring the light-emitting element, a third insulation structure may be prepared first. If the third insulation structure is a transparent insulation material, the third insulation structure is prepared first, which may ensure the proportion of the transparent area defined by the display panel and thus improve the light transmittance. Meanwhile, preparing the third insulation structure before preparing the first insulation structure may reduce the height difference between the light-emitting element and the upper surface of the array layer when preparing the first insulation structure, which is convenient for forming the first groove in the first insulation structure. In some embodiments, the curing temperature of the third insulation structure during preparation is lower than the melting point of the eutectic layer in the light-emitting element. Meanwhile, the refractive index of the third insulation structure may be adjusted to ensure that it is close to the refractive index of the adjacent film layer, so as to ensure that the light transmittance of the display panel at the third insulation structure is relatively large.

S250: Etch the third insulation structure to prepare a third groove.

S260: Fill a first insulation structure in the third groove.

Specifically, the preparation process of the third insulation structure may include coating, curing, and etching of the insulating layer. The third groove is formed in the third insulation structure through etching. The third groove is used to fill with the first insulation structure later.

In some embodiments, the display panel includes a first area and a second area, and the second area is located on one side of the first area. For the array layer and the light-emitting element located in the first area, the first area may be considered as the display light-emitting area of the display panel. In some embodiments, the orthographic projection of the third insulation structure onto the substrate is disposed on the side, of the orthographic projection of the first insulation structure onto the substrate, away from the orthographic projection of the light-emitting element onto the substrate. In some embodiments, the third insulation structure is disposed in the second area, and when the third insulation structure is a transparent insulation material, the second area may be considered as the display light-transmitting area in the display panel.

In some embodiments, the third insulation structure may be disposed in various ways. In one example, along the thickness direction of the substrate, the surface of the third insulation structure away from the substrate may be located on the side, of the surface of the light-emitting element away from the substrate, close to the substrate. In other words, along the thickness direction of the display panel, the distance between the surface of the third insulation structure away from the substrate and the substrate is smaller than the distance between the surface of the light-emitting element away from the substrate and the substrate, thereby ensuring the wide viewing angle display effect of the display panel.

In some embodiments, the surface of the third insulation structure away from the substrate may be flush with the surface of the light-emitting element away from the substrate. In other words, along the thickness direction of the display panel, the distance between the surface of the third insulation structure away from the substrate and the substrate is equal to the distance between the surface of the light-emitting element away from the substrate and the substrate, thereby ensuring the flatness of the overall structure of the display panel.

In some embodiments, along the thickness direction of the substrate, the surface of the third insulation structure away from the substrate may be located on the side, of the surface of the light-emitting element away from the substrate, away from the substrate. In other words, along the thickness direction of the display panel, the distance between the surface of the third insulation structure away from the substrate and the substrate is greater than the distance between the surface of the light-emitting element away from the substrate and the substrate. When the third endpoint of the second side surface in the second insulation subsection is synchronously adjusted in height with the third insulation structure, the anti-crosstalk effect of the display panel may be further improved.

In some embodiments, an insulating layer is coated on a side of the array layer away from the substrate. The insulating layer is then etched to form a first insulation structure. The insulating layer on a side of the light-emitting element away from the substrate is then removed.

Specifically, during the etching process of preparing the first insulation structure, an etching process is added to remove the insulating layer remaining on the side of the light-emitting element away from the substrate, thereby preventing the insulating layer from affecting the light-emitting effect of the light-emitting element, thereby ensuring the overall display performance of the display panel.

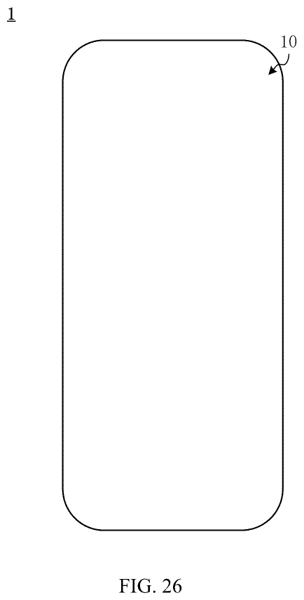

Based on the similar inventive concept, an embodiment of the present disclosure further provides a display device. FIG. 26 is a schematic structural diagram of a display device, in accordance with an embodiment of the present disclosure. As shown in FIG. 26, the display device 1 includes a display panel 10 described in the above embodiments. Accordingly, the display device 1 provided by the embodiment of the present disclosure has the corresponding beneficial effects of the above described display panels, which will not be repeated here. Exemplarily, the display device 1 may be an electronic device such as a mobile phone, a computer, a smart wearable device (e.g., a smartwatch), and a vehicle-mounted display device, which is not limited in the present disclosure.

It should be noted that the above descriptions are merely some embodiments of the present disclosure and the technical principles used. Those skilled in the art will understand that the present disclosure is not limited to the specific embodiments described herein. Various obvious changes, adjustments, and substitutions may be made by those skilled in the art without departing from the scope of protection of the present disclosure. Accordingly, although the present disclosure has been described in more detail through the above embodiments, the present disclosure is not limited to the above embodiments, and may include more other equivalent embodiments without departing from the principle of the present disclosure, where the scope of the present disclosure is determined by the scope of the appended claims.

What is claimed is:

1. A display panel, comprising:
a substrate;
an array layer, disposed on one side of the substrate;
a light-emitting element, disposed on a side of the array layer away from the substrate; and
a first insulation structure, disposed on a side of the array layer away from the substrate, and surrounding at least a portion of the light-emitting element, the first insulation structure including a first insulation subsection, wherein an orthographic projection of the first insulation subsection onto the substrate at least partially overlaps with an orthographic projection of the array layer onto the substrate, wherein:
the first insulation subsection includes a first side surface and a first bottom surface, the first side surface includes a first endpoint and a second endpoint, the first endpoint is located on a side of the second endpoint away from the array layer, along a first direction, a distance between the first endpoint and the light-emitting element is smaller than a distance between the second endpoint and the light-emitting element, the first bottom surface is connected to the second endpoint, and an orthographic projection of the first bottom surface onto the substrate is located on a side, of an orthographic projection of the first side surface onto the substrate, away from an orthographic projection of the light-emitting element onto the substrate; and
the first direction is parallel to a plane where the substrate is disposed.

2. The display panel according to claim 1, wherein the first insulation structure further includes a second insulation subsection, and the second insulation subsection is located on a side of the first insulation subsection away from the light-emitting element,
wherein the second insulation subsection includes a second side surface and a second bottom surface, the second side surface includes a third endpoint and a fourth endpoint, the third endpoint is located on a side of the fourth endpoint away from the array layer, along the first direction, a distance between the third endpoint and the light-emitting element is greater than a distance between the fourth endpoint and the light-emitting element, the second bottom surface is connected to the fourth endpoint, and an orthographic projection of the second bottom surface onto the substrate is located on a side, of an orthographic projection of the second side surface onto the substrate, close to an orthographic projection of the light-emitting element onto the substrate, and the first bottom surface and the second bottom surface are coplanar.

3. The display panel according to claim 2, wherein the first insulation subsection and the second insulation subsection both include a light-blocking structure.

4. The display panel according to claim 3, wherein:
along a thickness direction of the display panel, the first endpoint is flush with the third endpoint or is disposed on a side of the third endpoint close to the substrate, or the third endpoint is disposed on a side of the first endpoint close to the substrate; or
along a thickness direction of the display panel, the first endpoint is located on a side of the light-emitting element close to the substrate or is flush with a surface of the light-emitting element away from the substrate, or the first endpoint is closer to the substrate than a surface of the light-emitting element away from the substrate; or
along a thickness direction of the display panel, the third endpoint is located on a side of the light-emitting element away from the substrate, or the third endpoint is flush with a surface of the light-emitting element away from the substrate.

5. The display panel according to claim 3, wherein:
along the first direction, a width of the light-emitting element is L1;
along the first direction, a distance between first endpoints on two opposite sides of the light-emitting element is L2; and
$$( L 2 - L 1 ) > 0.$$

6. The display panel according to claim 2, wherein:
the first insulation structure further includes a first groove and a third insulation subsection, the first groove is at least partially surrounded by the first side surface, the first bottom surface, the second side surface, and the second bottom surface, and the third insulation subsection fills the first groove; and
the first insulation subsection and/or the second insulation subsection include a light-reflective structure, and the third insulation subsection includes a light-blocking structure.

7. The display panel according to claim 6, wherein:
a side of the third insulation subsection away from the substrate is flush with the first endpoint; and
compared to the third endpoint, the first endpoint is closer to the substrate; or the first endpoint is flush with the third endpoint.

8. The display panel according to claim 1, wherein the display panel includes a first area and a second area, and the second area is located on one side of the first area;
the array layer and the light-emitting element are located in the first area, the display panel further includes a third insulation structure, and the third insulation structure is disposed in the second area;
an orthographic projection of the third insulation structure onto the substrate is located on a side, of an orthographic projection of the first insulation structure onto the substrate, away from the orthographic projection of the light-emitting element onto the substrate; and
along a thickness direction of the substrate, a surface of the third insulation structure away from the substrate is located on a side, of a surface of the light-emitting element away from the substrate, close to the substrate, or the surface of the third insulation structure away from the substrate is flush with the surface of the light-emitting element away from the substrate.

9. The display panel according to claim 8, wherein the first insulation structure is in contact with the third insulation structure and/or the first insulation structure is in contact with the light-emitting element.

10. The display panel according to claim 8, wherein:
the first insulation structure further includes a second insulation subsection, and the second insulation subsection is disposed on a side of the first insulation subsection away from the light-emitting element;
the second insulation subsection includes a second side surface and a second bottom surface, the second side surface includes a third endpoint and a fourth endpoint, the third endpoint is located on a side of the fourth endpoint away from the array layer, along the first direction, a distance between the third endpoint and the light-emitting element is greater than a distance between the fourth endpoint and the light-emitting element, the second bottom surface is connected to the fourth endpoint, an orthographic projection of the second bottom surface onto the substrate is disposed on a side, of an orthographic projection of the second side surface to the substrate, close to an orthographic projection of the light-emitting element onto the substrate, and the first bottom surface and the second bottom surface are coplanar; and
along the thickness direction of the substrate, the third endpoint is located on a side, of a surface of the third insulation structure away from the substrate, close to the substrate, or the third endpoint is flush with the surface of the third insulation structure away from the substrate.

11. The display panel according to claim 1, wherein the first insulation subsection includes a light-blocking structure.

12. The display panel according to claim 11, wherein:
the display panel includes a first area and a second area, and the second area is located on one side of the first area;
the array layer and the light-emitting element are located in the first area, the display panel further includes a fourth insulation structure, and the fourth insulation structure is located in the second area;
an orthographic projection of the fourth insulation structure onto the substrate is located on a side, of an orthographic projection of the first insulation structure onto the substrate, away from an orthographic projection of the light-emitting element onto the substrate;
the array layer also includes a planarization layer; and
the fourth insulation structure is in the same layer as the planarization layer.

13. The display panel according to claim 1, wherein:
the array layer further includes a signal line; the display panel further includes a fifth insulation structure, and the fifth insulation structure is located on a side of the signal line away from the substrate; and
the fifth insulation structure includes a fourth insulation subsection, the fourth insulation subsection includes a second groove, and the second groove partially penetrates the fourth insulation subsection.

14. The display panel according to claim 13, wherein:
the fourth insulation subsection includes a light-blocking structure; or
the fifth insulation structure further includes a fifth insulation subsection, the fifth insulation subsection fills the second groove, the fourth insulation subsection includes a light-reflective structure, and the fifth insulation subsection includes a light-blocking structure.

15. The display panel according to claim 1, wherein:
the display panel includes a first area and a second area, the first area is located on one side of the second area, the array layer includes a pixel circuit and a driving circuit, the pixel circuit is electrically connected to the driving circuit and the light-emitting element respectively, and the pixel circuit is disposed in the first area, and the driving circuit is disposed in the second area;
the display panel further includes a transition area, wherein the transition area is located between the first area and the second area; and
the display panel further includes a sixth insulation structure, the sixth insulation structure includes a first light-blocking section and a second light-blocking section, wherein the first light-blocking section is disposed in the second zone, and the first light-blocking section is disposed on a side of the driving circuit away from the substrate, the second light-blocking section is disposed in the transition zone, and the second light-blocking section and the first light-blocking section are located on a same side of the substrate.

16. The display panel according to claim 15, wherein along a direction from the first area to the second area, the width of the transition area is D, wherein D≤40 μm.

17. The display panel according to claim 15, wherein the display panel further includes an insulating layer structure and/or a conductive structure, and the insulating layer structure and/or the conductive structure are located on a side of the second light-blocking portion close to the substrate.

18. The display panel according to claim 15, wherein the display panel further includes a seventh insulation structure, the seventh insulation structure is located on a side of the first light-blocking portion away from the second light-blocking portion, and the seventh insulation structure is located on a side of the driving circuit away from the substrate.

19. The display panel according to claim 15, wherein the driving circuit includes a plurality of metal wire routing layers, the metal wire routing layers include a first metal wire routing section, the first metal wire routing section is disposed on a side of the first light-blocking section close to the substrate, the first light-blocking section covers the first metal wire routing section, and the first metal wire routing section includes at least one hollow unit.

20. A display device, comprising a display panel, wherein the display panel includes:
a substrate;
an array layer, disposed on one side of the substrate;
a light-emitting element, disposed on a side of the array layer away from the substrate; and
a first insulation structure, disposed on a side of the array layer away from the substrate, and surrounding at least a portion of the light-emitting element, the first insulation structure including a first insulation subsection, wherein an orthographic projection of the first insulation subsection onto the substrate at least partially overlaps with an orthographic projection of the array layer onto the substrate, wherein:
the first insulation subsection includes a first side surface and a first bottom surface, the first side surface includes a first endpoint and a second endpoint, the first endpoint is located on a side of the second endpoint away from the array layer, along a first direction, a distance between the first endpoint and the light-emitting element is smaller than a distance between the second endpoint and the light-emitting element, the first bottom surface is connected to the second endpoint, and an orthographic projection of the first bottom surface onto the substrate is located on a side, of an orthographic projection of the first side surface onto the substrate, away from an orthographic projection of the light-emitting element onto the substrate; and
the first direction is parallel to a plane where the substrate is disposed.
